(19) United States
(12) Patent Application Publication
(10) Pub. No.: US 2026/0146329 A1
(43) Pub. Date: May 28, 2026

(54) SEMICONDUCTOR PROCESSING SYSTEMS, CHEMICAL VAPOR DEPOSITION (CVD) REACTORS AND METHODS FOR DEPOSITING MATERIAL ON SEMICONDUCTOR SUBSTRATES WITH UNIFORM TEMPERATURE AND GAS FLOW ACROSS THE SUBSTRATE SURFACE

(71) Applicant: Tokyo Electron Limited, Tokyo (JP)

(72) Inventors: Anthony Dip, Austin, TX (US); Melvin Verbaas, Austin, TX (US); Toru Ishii, Oshu City (JP); George Eyres, Dublin (IE); Ioan Domsa, Dublin (IE); Noel O'Shaughnessy, Dublin (IE); Ian Colgan, Dublin (IE)

(21) Appl. No.: 19/339,014

(22) Filed: Sep. 24, 2025

Related U.S. Application Data
(60) Provisional application No. 63/725,209, filed on Nov. 26, 2024.

(51) Int. Cl. C23C 16/46; C23C 16/02; C23C 16/44; C23C 16/458; H01L 21/02

(52) U.S. Cl. CPC C23C 16/46; C23C 16/0227; C23C 16/4412; C23C 16/4586; H10P 14/24; H10P 14/6334

(57) ABSTRACT

The present disclosure relates to the processing of semiconductor substrates. The present disclosure provides various embodiments of substrate processing systems, chemical vapor deposition (CVD) reactors and CVD deposition methods that utilize improved substrate heating and gas flow distribution techniques to deposit materials uniformly across a substrate surface. Multiple chambers may be utilized and a plurality of gas inlets may also be utilized.

This application claims priority to U.S. Provisional Application No. 63/725,209 entitled “Semiconductor Processing Systems, Chemical Vapor Deposition (CVD) Reactors And Methods For Depositing Material On Semiconductor Substrates With Uniform Temperature And Gas Flow Across The Substrate Surface”, filed Nov. 26, 2024, the disclosure of which is expressly incorporated herein by reference in its entirety.

### TECHNICAL FIELD

The present disclosure relates to the processing of semiconductor substrates. In particular, it provides improved substrate processing systems, chemical vapor deposition (CVD) chambers and methods for depositing materials on semiconductor substrates.

### BACKGROUND

Silicon-containing films, such as polycrystalline silicon (poly-Si) and epitaxial silicon (Si), silicon germanium (SiGe), silicon germanium carbide (SiGeC), silicon carbide (SiC), silicon nitride (SiN), silicon carbonitride (SiCN) and silicon carboxide (SiCO), are used for a wide variety of applications in the semiconductor industry. Various physical and/or chemical deposition techniques are routinely employed for silicon-containing film deposition including chemical vapor deposition (CVD), physical vapor deposition (PVD), atomic layer deposition (ALD), etc. While more than one technique can be used to deposit a particular film, the preferred deposition method is determined by considering the desired film properties, physical and/or chemical constraints imposed by the device being fabricated and economic factors associated with the manufacturing process. The selected deposition process is often one that provides an acceptable trade-off to address the pertinent technical and economic concerns.

Thermally excited chemical vapor deposition (CVD) is a common technique used to deposit materials for integrated circuit fabrication. In a typical CVD process, a substrate (wafer) is placed in a low-pressure process chamber and maintained at a controlled temperature. The substrate is exposed to a gaseous ambient of precursor gas(es) that contain the chemical elements to be incorporated in the film. The precursor gas(es) combine via one or more chemical reactions to form a solid film on the substrate surface. The conditions of the process chamber, substrate, and precursor gas(es) are typically chosen to favor chemical reactions that produce films with the desired physical, chemical, and electrical properties.

A wide variety of CVD process chambers and methods have been used to deposit silicon-containing films and other films on a substrate surface. The different types of CVD process chambers and methods currently in use can be classified by various operating conditions (such as chamber pressure, vapor characteristics, etc.), the heating method used to heat the substrate (e.g., hot wall vs cold wall CVD) and the process (e.g., plasma-enhanced CVD, atomic layer CVD, rapid thermal CVD, photo-initiated CVD, laser CVD, etc.) used to decompose the precursor gas(es) and/or control the gas-phase reactions that lead to film deposition.

Cold wall CVD process chambers (reactors) are considered an attractive option for large scale production of silicon-containing films with high throughput and reduced production cost. In hot wall CVD, the entire process chamber (including the chamber walls and substrate) is heated to achieve a desired temperature. Cold wall CVD, on the other hand, only heats the substrate keeping the chamber walls at room temperature. As such, cold wall CVD reactors have several advantages over hot wall CVD reactors. For example, cold wall CVD reactors have rapid substrate heating and cooling times, which is beneficial for achieving fast growth. In addition, cold wall CVD reactors have reduced gas-phase chemical reactions, which contributes to better control of the film quality and produces less deposition on the chamber walls (since only the substrate is heated). Furthermore, a cold wall CVD reactor has a lower heat capacity (since it uses a local heater positioned near the substrate), and therefore, consumes less power. Thus, cold wall CVD reactors provide fast growth with better control of the film quality and less power consumption. There are several types of cold wall CVD reactors that differ depending on the heat source used to heat the substrate. Examples of heat sources commonly used in cold wall CVD reactors include magnetic induction heating sources, resistively heated stages and radiant heat sources that use heating lamps to heat the substrate surface.

In CVD processes, the deposition rate of a precursor gas on the substrate surface is proportional to the substrate temperature. Unfortunately, conventional cold wall CVD chamber designs struggle to maintain uniform temperature across the substrate surface. Because the radiative heat loss is greater at the edge than the center of the substrate, simply applying heat in a uniform manner across the substrate often results in significant temperature differences between the center and outer portions of the substrate. The temperature variations across the substrate surface cause a non-uniform thickness of material to be deposited across the substrate surface. One approach to compensate for the higher heat loss at the edge of the substrate is to use a multi-zone heat source to apply more heat energy to the substrate edge than the center. However, such a technique is not entirely effective since it is virtually impossible to direct the additional heat energy to only the substrate edge, especially when using inductive and radiative heat sources.

When the precursor gas(es) is/are held at low partial pressures (e.g., less than approximately 10 mTorr), the material deposition rate is primarily a function of the substrate temperature. In some cases, the material deposition rate may be increased by increasing the partial pressure of the precursor gas(es) supplied to the CVD reactor. At higher partial pressures, the material deposition rate is affected not only by substrate temperature, but also by the distribution pattern of the precursor gas(es) over the substrate surface. Thus, the substrate temperature uniformity and the precursor gas distribution uniformity across the substrate surface affects the deposition uniformity of CVD-deposited films.

Conventional CVD reactor designs attempt to create a more uniform film deposition by controlling the gas flow profile of precursor and carrier gases flowing laterally across the substrate surface. The precursor and carrier gases, which are supplied from one or more gas injector ports arranged on one side of the substrate, flow laterally across the substrate surface before exiting an exhaust port arranged on an opposite side of the substrate. These reactor designs typically use a high carrier gas flow rate (e.g., 35-75 slm) to create a mass transport limited laminar boundary layer, which flows laterally across the substrate surface. Unfortunately, the high velocities at which the precursor and carrier gases enter the CVD reactor, as well as the turbulence generated within the chamber due to gases striking objects within the CVD reactor, make it nearly impossible to achieve a truly laminar, uniform gas flow within the CVD reactor.

Accordingly, it would be desirable to provide improved substrate processing systems, CVD reactors and methods for depositing materials (such as silicon-containing materials) on semiconductor substrates with uniform temperature and gas flow across the substrate surface.

### SUMMARY

The present disclosure provides various embodiments of substrate processing systems, chemical vapor deposition (CVD) reactors and CVD deposition methods that utilize improved substrate heating and gas flow distribution techniques to deposit materials uniformly across a substrate surface.

In the disclosed embodiments, an improved CVD reactor design is used to provide uniform temperature and gas flow across a substrate surface to improve uniformity of a material deposited on the substrate surface. The improved CVD reactor includes a reactor body having: (a) an upper process chamber configured to receive a semiconductor substrate, and (b) a lower heating chamber configured to provide heat to the semiconductor substrate during a CVD process performed on a surface of the semiconductor substrate. The improved CVD reactor further includes: (i) a susceptor positioned within the upper process chamber for holding the semiconductor substrate during the CVD process, (ii) a ceramic resistive heater positioned within the lower heating chamber for generating the heat provided to the semiconductor substrate during the CVD process, and (iii) a conductive heat spreader plate coupled between the ceramic resistive heater positioned within the lower heating chamber and the susceptor positioned within the upper process chamber. The conductive heat spreader plate conducts the heat generated by the ceramic resistive heater to the susceptor to heat the semiconductor substrate with uniform heat distribution across the semiconductor substrate.

The conductive heat spreader plate enables direct conductive heating of the substrate and provides the uniform heat distribution needed to deposit a material layer uniformly across the substrate surface. In some embodiments, the conductive heat spreader plate provided between the ceramic resistive heater and the susceptor may provide less than about 1° C. temperature variation across the substrate surface. By providing uniform heat distribution across the substrate surface, the conductive heat spreader plate enables a uniform thickness of the material to be deposited across the surface of the semiconductor substrate.

In addition to providing uniform substrate temperature, the improved CVD reactor uses a novel gas distribution technique to improve material deposition uniformity. Unlike conventional gas distribution techniques, which direct gas flow laterally across a substrate surface, the improved CVD reactor uses a plurality of gas inlets distributed around a periphery of the upper process chamber to provide uniform gas flow across the substrate surface to a central exhaust port coupled to the upper process chamber. By providing uniform heat distribution and uniform gas flow across the substrate surface, the improved CVD reactor further improves the uniformity of the material to be deposited across the surface of the semiconductor substrate.

While the embodiments disclosed herein are used to deposit a uniform layer of silicon-containing material (such as, e.g., silicon (Si), poly-silicon (poly-Si), silicon germanium (SiGe), silicon germanium carbide (SiGeC), silicon carbide (SiC), silicon nitride (SiN), silicon carbonitride (SiCN), silicon carboxide (SiCO), etc.) on the substrate surface, it is recognized that the techniques described herein can alternatively be used to deposit other materials (including those that do not contain silicon) uniformly across the substrate surface.

According to one embodiment, a semiconductor processing system as described herein may include a chemical vapor deposition (CVD) reactor, comprising: (i) a reactor body having an upper process chamber configured to receive a semiconductor substrate and a lower heating chamber configured to provide heat to the semiconductor substrate during a CVD process performed on a surface of the semiconductor substrate; (ii) a susceptor positioned within the upper process chamber, wherein the semiconductor substrate is mounted on or above the susceptor during the CVD process; (iii) a ceramic resistive heater positioned within the lower heating chamber, wherein the ceramic resistive heater generates the heat provided to the semiconductor substrate during the CVD process; and (iv) a conductive heat spreader coupled between the ceramic resistive heater and the susceptor, wherein the conductive heat spreader conducts the heat generated by the ceramic resistive heater to the susceptor to heat the semiconductor substrate with uniform heat distribution across the semiconductor substrate. In some embodiments, the CVD reactor may further comprise: (v) a central exhaust port coupled to the upper process chamber; and (vi) a plurality of gas inlets distributed around a periphery of the upper process chamber, wherein the plurality of gas inlets supply one or more process gases to the upper process chamber to pressurize the upper process chamber and provide uniform gas flow of the one or more process gases across the surface of the semiconductor substrate to the central exhaust port. In some embodiments, the CVD reactor may further comprise: (v) a central exhaust port coupled to the upper process chamber; and (vi) a plurality of gas inlets distributed around a periphery of the upper process chamber, wherein the plurality of gas inlets supply one or more process gases to the upper process chamber to pressurize the upper process chamber and provide uniform gas flow of the one or more process gases across the surface of the semiconductor substrate to the central exhaust port.

In some embodiments, the CVD reactor may further comprise a lower gas inlet coupled to the lower heating chamber, wherein the lower gas inlet supplies an inert gas to the lower heating chamber to pressurize the lower heating chamber, and a lower exhaust port coupled to the lower heating chamber to remove the inert gas supplied to the lower heating chamber. By coupling the plurality of gas inlets and the central exhaust port to the upper process chamber, and the lower gas inlet and the lower exhaust port to the lower heating chamber, the upper process chamber and the lower heating chamber can be independently pressurized to equalize pressure in the upper process chamber and the lower heating chamber during the CVD process.

In some embodiments, the CVD reactor may further comprise a pedestal that is configured to: (a) support the semiconductor substrate, (b) transport the semiconductor substrate in and out of the upper process chamber through a loading port coupled to the reactor body, and (c) rest upon an upper surface of the susceptor once transferred into the upper process chamber. If a pedestal is included, the pedestal may transfer the heat, which is generated by the ceramic resistive heater and conducted through the conductive heat spreader and the susceptor, to the semiconductor substrate. In doing so, the pedestal may further improve the uniform heat distribution across the semiconductor substrate.

The conductive heat spreader, the susceptor and the pedestal may each be composed of thermally conductive materials. However, the conductive heat spreader, the susceptor and the pedestal may not necessarily be formed of the same material. In some embodiments, the conductive heat spreader may comprise a metal material with a high melting point and good thermal conductance, such as tungsten (W), chromium (Cr), osmium (Os), etc., or an alloy thereof. The susceptor and the pedestal (if included) may each comprise a material that is compatible with the processing environment and has at least some resistance to dry chemical etching. Although thermal conductive, the susceptor and the pedestal are not required to have thermal conductivity. In some embodiments, the susceptor and the pedestal (if included) may each be composed of silicon carbide (SiC), graphite or a metal material. In one example, the conductive heat spreader may be composed of tungsten and the susceptor and the pedestal may each be composed of quartz.

In some embodiments, the conductive heat spreader may be in direct thermal contact with an upper surface of the ceramic resistive heater and a lower surface of the susceptor. In other embodiments, the conductive heat spreader may be in: (a) direct thermal contact with an upper surface of the ceramic resistive heater, and (b) indirect thermal contact with a lower surface of the susceptor. In one example, the conductive heat spreader may be in indirect thermal contact with a lower surface of the susceptor when a quartz window is coupled between the upper surface the conductive heat spreader and the lower surface of the susceptor. In such embodiments, the quartz window may conductively and radiatively transfer the heat, which is generated by the ceramic resistive heater and conducted through the conductive heat spreader, to the susceptor.

In some embodiments, the CVD reactor may further comprise a water-cooled support plate positioned within the lower heating chamber, wherein the water-cooled support plate provides structural support for the ceramic resistive heater and assists in cooling the ceramic resistive heater. In some embodiments, the CVD reactor may further comprise a water channel within walls of the reactor body, wherein the water channel is configured to cool the upper process chamber and the lower heating chamber.

In some embodiments, the ceramic resistive heater may comprise a plurality of pyrolytic graphite (PG) resistive heating elements, a plurality of power connectors electrically connected to the plurality of PG resistive heating elements, and a pyrolytic boron nitride (PBN) upper layer formed above a PBN backplate.

In some embodiments, the ceramic resistive heater may comprise multiple heating zones, wherein each heating zone comprises a subset of the PG resistive heating elements and at least two of the power connectors, which are electrically connected to the subset of PG resistive heating elements included within each heating zone. In such embodiments, a temperature of each heating zone may be independently controlled by independently controlling an amount of current supplied to the subset of PG resistive heating elements included within each heating zone.

The power connectors may be configured in a wide variety of ways. In some embodiments, for example, the plurality of power connectors may extend through a thickness of the ceramic resistive heater, such that a terminal end of the power connectors is exposed on an upper surface of the ceramic resistive heater. However, this configuration may create cool points on the upper heating surface of the ceramic resistive heater, which may result in non-uniform heating of the substrate surface. In other embodiments, the plurality of power connectors may be arranged peripherally around a circumference of the ceramic resistive heater and coupled to the plurality of PG resistive heating elements through PG interconnects to improve substrate temperature uniformity. Alternatively, substrate temperature uniformity may be improved by positioning the plurality of power connectors below a lower surface of the ceramic resistive heater to avoid interfering with an upper surface of the ceramic resistive heater. In some embodiments, the CVD reactor may further comprise a water-cooled support plate positioned within the lower heating chamber, wherein the water-cooled support plate provides structural support for the ceramic resistive heater and assists in cooling the ceramic resistive heater, and the plurality of power connectors may be positioned below the water-cooled support plate to avoid interfering with an upper surface of the ceramic resistive heater.

In some embodiments, the upper process chamber and the lower heating chamber may each comprise circular inner sidewalls. In such embodiments, the plurality of gas inlets may be equally spaced around the circular inner sidewall of the upper process chamber, and configured to direct gas flow of the one or more process gases along the circular inner sidewall of the upper process chamber in a clockwise direction or a counter-clockwise direction. In such embodiments, the gas flow may be exhausted through the central exhaust port to redirect the gas flow radially across the surface of the semiconductor substrate and provide the uniform gas flow of the one or more process gases across the surface of the semiconductor substrate.

In other embodiments, the upper process chamber and the lower heating chamber may each comprise U-shaped inner sidewalls. In such embodiments, the upper process chamber may further comprise a gas flow plenum having an angled lower portion coupled to a circular upper portion, which partially surrounds the susceptor and comprises a gas flow slit. In such embodiments, the plurality of gas inlets may comprise: (a) a first set of gas inlets positioned along the U-shaped inner sidewall of the upper process chamber, wherein the first set of gas inlets is configured to direct a gas flow of the one or more process gases to the angled lower portion of the gas flow plenum, and (b) a second set of gas inlets positioned along the U-shaped inner sidewall of the upper process chamber, wherein the second set of gas inlets is configured to direct the gas flow of the one or more process gases around the circular upper portion and through the gas flow slit of the circular upper portion. In such embodiments, the gas flow directed from the first set of gas inlets and the second set of gas inlets may be exhausted through the central exhaust port to redirect the gas flow radially across the surface of the semiconductor substrate and provide the uniform gas flow of the one or more process gases across the surface of the semiconductor substrate.

In some embodiments, the CVD reactor may further comprise a quartz liner on interior walls of the upper process chamber to protect the interior walls of the upper process chamber from the one or more process gases supplied to the upper process chamber during the CVD process.

According to another embodiment, a method is provided herein for depositing material on a semiconductor substrate. In general, the method may include mounting the semiconductor substrate on or above a susceptor positioned within an upper process chamber of a chemical vapor deposition (CVD) reactor, supplying one or more process gases to the upper process chamber of the CVD reactor, and heating the semiconductor substrate to a material deposition temperature. The material deposition temperature decomposes the one or more process gases supplied to the upper process chamber to deposit a material on a surface of the semiconductor substrate. In the present disclosure, the semiconductor substrate is heated to the material deposition temperature by: (a) generating heat within a lower heating chamber of the CVD reactor using a ceramic resistive heater positioned within the lower heating chamber of the CVD reactor, and (b) conducting the heat generated by the ceramic resistive heater through a conductive heat spreader to the susceptor. The conductive heat spreader distributes the heat uniformly across the susceptor and the semiconductor substrate. In this embodiment, the method may deposit a uniform thickness of the material across the surface of the semiconductor substrate by distributing the heat uniformly across the semiconductor substrate.

In some embodiments, said supplying the one or more process gases to the upper process chamber of the CVD reactor may comprise supplying the one or more process gases via a plurality of gas inlets, which are distributed around a periphery of the upper process chamber to provide uniform gas flow of the one or more process gases across the surface of the semiconductor substrate to a central exhaust port coupled to the upper process chamber. In such embodiments, said depositing the uniform thickness of the material across the surface of the semiconductor substrate is achieved by: (a) distributing the heat uniformly across the semiconductor substrate, and (b) providing the uniform gas flow of the one or more process gases across the surface of the semiconductor substrate.

In some embodiments, said supplying the one or more process gases to the upper process chamber of the CVD reactor may comprise supplying a silicon-containing gas to the upper process chamber of the CVD reactor, said heating the semiconductor substrate to the material deposition temperature comprises heating the semiconductor substrate to a temperature within a range of 500° C. to 900°C. When a silicon-containing gas is supplied to the upper process chamber, the material deposited across the surface of the semiconductor substrate may comprise a silicon-containing material, such as but not limited to, silicon (Si), poly-silicon (poly-Si), silicon germanium (SiGe), silicon germanium carbide (SiGeC), silicon carbide (SiC), silicon nitride (SiN), silicon carbonitride (SiCN) or silicon carboxide (SiCO). The silicon-containing material deposited across the substrate surface may be undoped, in some embodiments, or doped with an impurity, such as boron (B), phosphorus (P), arsenic (As) or indium (In).

In some embodiments, the method may further comprise precleaning the surface of the semiconductor substrate before supplying the one or more process gases to the upper process chamber of the CVD reactor. For example, the surface of the semiconductor substrate may be precleaned by: (a) supplying one or more precleaning gases to the upper process chamber of the CVD reactor, and (b) heating the semiconductor substrate to a precleaning temperature. The precleaning temperature causes the one or more precleaning gases to react with and remove contaminants from the surface of the semiconductor substrate. In the present disclosure, the semiconductor substrate may be heated to the precleaning temperature by: (a) generating heat within the lower heating chamber of the CVD reactor using the ceramic resistive heater positioned within the lower heating chamber of the CVD reactor, and (b) conducting the heat generated by the ceramic resistive heater through the conductive heat spreader to the susceptor. The conductive heat spreader distributes the heat uniformly across the susceptor and the semiconductor substrate.

In some embodiments, said supplying the one or more precleaning gases to the upper process chamber of the CVD reactor may comprise supplying hydrogen (H₂) gas to the upper process chamber of the CVD reactor, and said heating the semiconductor substrate to the precleaning temperature comprises heating the semiconductor substrate to a temperature within a range of 700° C. to 1100° C.

According to yet another embodiment, another method is provided herein for depositing material on a semiconductor substrate. In general, the method may include mounting the semiconductor substrate on or above a susceptor positioned within an upper process chamber of a chemical vapor deposition (CVD) reactor, and supplying one or more process gases to the upper process chamber via a plurality of gas inlets, which are distributed around a periphery of the upper process chamber to provide uniform gas flow of the one or more process gases across the surface of the semiconductor substrate to a central exhaust port coupled to the upper process chamber. The method may further include heating the semiconductor substrate to a material deposition temperature, wherein the material deposition temperature decomposes the one or more process gases supplied to the upper process chamber to deposit a material on a surface of the semiconductor substrate. In the present disclosure, the semiconductor substrate is heated to the material deposition temperature by: (a) generating heat within a lower heating chamber of the CVD reactor using a heater positioned within the lower heating chamber of the CVD reactor, and (b) conducting the heat generated by the ceramic resistive heater to the susceptor positioned within the upper process chamber of the CVD reactor, wherein the heat conducted to the susceptor is distributed uniformly across the susceptor and the semiconductor substrate. The method further includes depositing a uniform thickness of the material across the surface of the semiconductor substrate by: (a) distributing the heat uniformly across the semiconductor substrate, and (b) providing the uniform gas flow of the one or more process gases across the surface of the semiconductor substrate.

In some embodiments, the plurality of gas inlets may be equally spaced around a circular inner sidewall of the upper process chamber. In such embodiments, said supplying the one or more process gases via the plurality of gas inlets may comprise: (a) utilizing the plurality of gas inlets to direct a gas flow of the one or more process gases along the circular inner sidewall of the upper process chamber in a clockwise direction or a counter-clockwise direction, and (b) exhausting the gas flow of the one or more process gases through the central exhaust port to redirect the gas flow of the one or more process gases radially across the surface of the semiconductor substrate and provide the uniform gas flow of the one or more process gases across the surface of the semiconductor substrate.

In some embodiments, said supplying the one or more process gases to the upper process chamber of the CVD reactor may comprise supplying a silicon-containing gas to the upper process chamber of the CVD reactor. In such embodiments, the material deposited across the surface of the semiconductor substrate may comprise a silicon-containing material, such as but not limited to, silicon (Si), poly-silicon (poly-Si), silicon germanium (SiGe), silicon germanium carbide (SiGeC), silicon carbide (SiC), silicon nitride (SiN), silicon carbonitride (SiCN) or silicon carboxide (SiCO). The silicon-containing material deposed across the substrate surface may be undoped, in some embodiments, or doped with an impurity, such as boron (B), phosphorus (P), arsenic (As) or indium (In).

In some embodiments, said heating the semiconductor substrate to the material deposition temperature may comprise heating the semiconductor substrate to a temperature within a range of 500° C. to 900° C. In some embodiments, the method may further include cooling the semiconductor substrate to a temperature within a range of 400° C. to 200° C. before removing the semiconductor substrate from the upper process chamber of the CVD reactor.

In some embodiments, the method may further comprise precleaning the surface of the semiconductor substrate before supplying the one or more process gases to the upper process chamber of the CVD reactor. For example, the surface of the semiconductor substrate may be precleaned by: (a) supplying one or more precleaning gases to the upper process chamber of the CVD reactor, and (b) heating the semiconductor substrate to a precleaning temperature. The precleaning temperature causes the one or more precleaning gases to react with and remove contaminants from the surface of the semiconductor substrate. In the present disclosure, the semiconductor substrate may be heated to the precleaning temperature by: (a) generating heat within the lower heating chamber of the CVD reactor using the heater positioned within the lower heating chamber of the CVD reactor, and (b) conducting the heat generated by the heater to the susceptor positioned within the upper process chamber of the CVD reactor, wherein the heat conducted to the susceptor is distributed uniformly across the susceptor and the semiconductor substrate.

In some embodiments, said supplying the one or more precleaning gases to the upper process chamber of the CVD reactor may comprise supplying hydrogen (H₂) gas to the upper process chamber of the CVD reactor, and said heating the semiconductor substrate to the precleaning temperature comprises heating the semiconductor substrate to a temperature within a range of 700° C. to 1100° C. In some embodiments, after said precleaning the surface of the semiconductor substrate, the method may further comprise cooling the semiconductor substrate to the material deposition temperature before supplying the one or more process gases to the upper process chamber of the CVD reactor.

As noted above and described further herein, the present disclosure provides various embodiments of processing systems and methods for depositing materials uniformly across a surface of a semiconductor substrate. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a simplified block diagram illustrating one embodiment of a semiconductor processing system comprising a chemical vapor deposition (CVD) reactor in accordance with the present disclosure.

FIG. 1B is a cross-sectional view illustrating a CVD reactor in accordance with another embodiment of the present disclosure.

FIG. 1C is a cross-sectional view illustrating a CVD reactor in accordance with another embodiment of the present disclosure.

FIG. 1D is a cross-sectional view illustrating a pedestal in accordance with one embodiment of the present disclosure.

FIG. 2A is a perspective view illustrating a CVD reactor er in accordance with one embodiment of the present disclosure.

FIG. 2B is a side view of the CVD reactor shown in FIG. 2A.

FIG. 2C is a top view of the CVD reactor shown in FIG. 2A.

FIG. 2D is a cross-sectional view of the CVD reactor shown in FIG. 2A through line C-C.

FIGS. 3A-3G are cross-sectional views of the CVD reactor shown in FIG. 2A through line C-C, illustrating one embodiment of a process flow that may be performed within the CVD reactor to deposit material uniformly across a surface of a semiconductor substrate.

FIG. 4 is a cross-sectional view illustrating a CVD reactor in accordance with another embodiment of the present disclosure.

FIG. 5A is a perspective view illustrating a CVD reactor in accordance with yet another embodiment of the present disclosure.

FIG. 5B is a side view of the CVD reactor shown in FIG. 5A.

FIG. 5C is a top view of the CVD reactor shown in FIG. 5A.

FIG. 5D is a cross-sectional view of the CVD reactor shown in FIG. 5A through line A-A.

FIG. 6A is a perspective view of a ceramic resistive heater in accordance with one embodiment of the present disclosure.

FIG. 6B is a cross-section view through a portion of the ceramic resistive heater shown in FIG. 6A illustrating the pyrolytic graphite (PG) resistive heating elements formed between a pyrolytic boron nitride (PBN) upper layer and PBN backplate.

FIG. 7 is a top view of a ceramic resistive heater having multiple heating zones.

FIG. 8A is a top view of the ceramic resistive heater shown in FIGS. 6A-6B, illustrating the power connectors extending through the base plates and the upper heating surface of the ceramic resistive heater.

FIG. 8B is a cross-section view through the ceramic resistive heater shown in FIG. 8A.

FIG. 9A is a top view of an alternative embodiment of a ceramic resistive heater having power connectors that connect to the base plates below the water cooling plate, so as not to interfere with the upper heating surface of the ceramic resistive heater.

FIG. 9B is a cross-section view through the ceramic resistive heater shown in FIG. 9A.

FIG. 10A is a top view of a ceramic resistive heater having multiple heating zones, wherein the electrical connections to each heating zone are arranged peripherally around the circumference of the ceramic resistive heater.

FIG. 10B is a cross-section view through a portion of the ceramic resistive heater shown in FIG. 10A illustrating the electrical connections arranged peripherally around the circumference of the ceramic resistive heater.

FIG. 11 is a flowchart diagram illustrating one embodiment of a method that utilizes the techniques described herein to deposit material on a semiconductor substrate using a CVD process.

FIG. 12 is a top view of one embodiment of a gas distribution system designed to provide uniform gas flow across a substrate surface to a central exhaust port, illustrating the velocity and direction of gas flow provided across the substrate surface.

FIG. 13A depicts simulation results obtained from an example silicon germanium (SiGe) CVD process illustrating deposition rate contours of SiGe deposited across the substrate surface (expressed in angstroms per minute, Å/min) using the gas distribution system shown in FIG. 12.

FIG. 13B depicts the gas flow path lines from the gas distribution system shown in FIG. 12 overset on the deposition rate contours shown in FIG. 13A.

FIG. 13C illustrates the deposition rate contours of SiGe deposited across the substrate surface (expressed in angstroms per minute, Å/min) using the gas distribution system shown in FIG. 12 with the additional shutter added to the loading port.

FIG. 14A is a perspective view of another embodiment of a gas distribution system designed to provide uniform gas flow across a substrate surface to a central exhaust port.

FIG. 14B is a perspective top view of the gas distribution system shown in FIG. 14A illustrating the velocity and direction of gas flow provided across the substrate surface.

FIG. 15A depicts simulation results obtained from an example silicon germanium (SiGe) CVD process illustrating deposition rate contours of SiGe deposited across the substrate surface (expressed in angstroms per minute, Å/min) using the gas distribution system shown in FIG. 14A.

FIG. 15B depicts the gas flow path lines from the gas distribution system shown in FIG. 14A overset on the deposition rate contours shown in FIG. 15A.

FIG. 16 is a flowchart diagram illustrating another embodiment of a method that utilizes the techniques described herein to deposit material on a semiconductor substrate using a CVD process.

### DETAILED DESCRIPTION

The present disclosure provides various embodiments of substrate processing systems, chemical vapor deposition (CVD) reactors and CVD deposition methods that utilize improved substrate heating and gas flow distribution techniques to deposit materials uniformly across a substrate surface.

In the disclosed embodiments, an improved CVD reactor design is used to provide uniform temperature and gas flow across a substrate surface to improve uniformity of a material deposited on the substrate surface. The improved CVD reactor includes a reactor body having: (a) an upper process chamber configured to receive a semiconductor substrate, and (b) a lower heating chamber configured to provide heat to the semiconductor substrate during a CVD process performed on a surface of the semiconductor substrate. The improved CVD reactor further includes: (i) a susceptor positioned within the upper process chamber for holding the semiconductor substrate during the CVD process, (ii) a ceramic resistive heater positioned within the lower heating chamber for generating the heat provided to the semiconductor substrate during the CVD process, and (iii) a conductive heat spreader plate coupled between the ceramic resistive heater positioned within the lower heating chamber and the susceptor positioned within the upper process chamber. The conductive heat spreader plate conducts the heat generated by the ceramic resistive heater to the susceptor to heat the semiconductor substrate with uniform heat distribution across the semiconductor substrate.

The conductive heat spreader plate enables direct conductive heating of the substrate and provides the uniform heat distribution needed to deposit a material layer uniformly across the substrate surface. In some embodiments, the conductive heat spreader plate provided between the ceramic resistive heater and the susceptor may provide less than about 1° C. temperature variation across the substrate surface. By providing uniform heat distribution across the substrate surface, the conductive heat spreader plate enables a uniform thickness of the material to be deposited across the surface of the semiconductor substrate.

In addition to providing uniform substrate temperature, the improved CVD reactor uses a novel gas distribution technique to improve material deposition uniformity. Unlike conventional gas distribution techniques, which direct gas flow laterally across a substrate surface, the improved CVD reactor uses a plurality of gas inlets distributed around a periphery of the upper process chamber to provide uniform gas flow across the substrate surface to a central exhaust port coupled to the upper process chamber. By providing uniform heat distribution and uniform gas flow across the substrate surface, the improved CVD reactor further improves the uniformity of the material to be deposited across the surface of the semiconductor substrate.

The techniques disclosed herein may be utilized during the processing of a wide range of substrates. The substrate may be any substrate for which the patterning of the substrate is desirable. For example, in one embodiment, the substrate may be a semiconductor substrate having one or more semiconductor processing layers (all of which together may comprise the substrate) formed thereon. Thus, in one embodiment, the substrate may be a semiconductor substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon.

The techniques disclosed herein may be used to deposit a wide variety of materials on a substrate surface. In some embodiments, the techniques disclosed herein may be used to deposit a uniform layer of a silicon-containing material on the substrate surface. Examples of silicon-containing materials that may be deposited using the techniques disclosed herein include, but are not limited to, silicon (Si), poly-silicon (poly-Si), silicon germanium (SiGe), silicon germanium carbide (SiGeC), silicon carbide (SiC), silicon nitride (SiN), silicon carbonitride (SiCN) and silicon carboxide (SiCO), each of which is undoped or doped with boron (B), phosphorus (P), arsenic (As) or indium (In). In example embodiments, the disclosed techniques may be used to deposit a uniform thickness of silicon germanium (SiGe) across the substrate surface. It is recognized, however, that the techniques disclosed herein can alternatively be used to deposit other materials uniformly across the substrate surface. For example, the techniques disclosed herein can be used to deposit nitrogen-containing or oxygen-containing materials uniformly across the substrate surface.

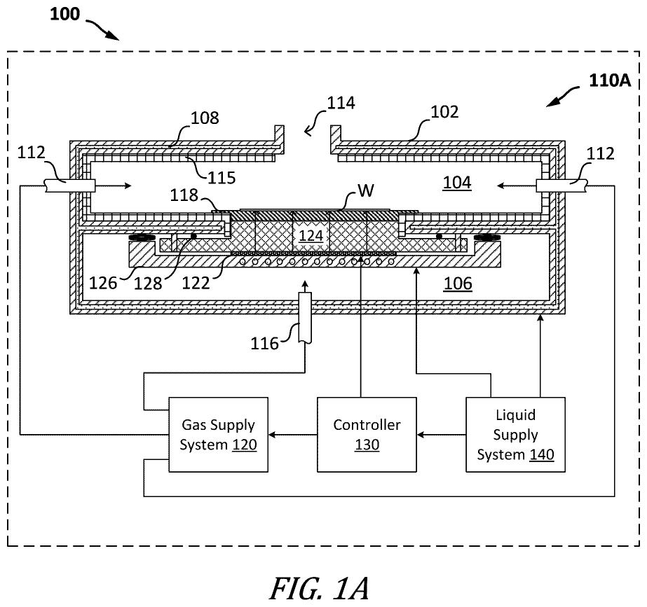

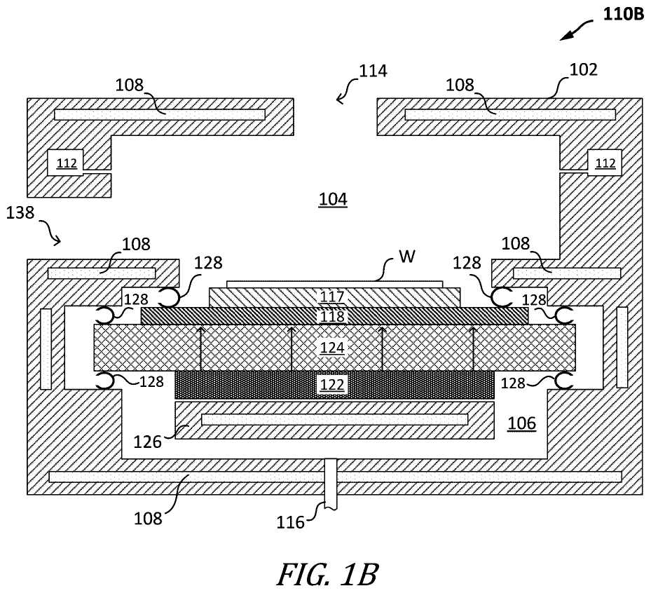

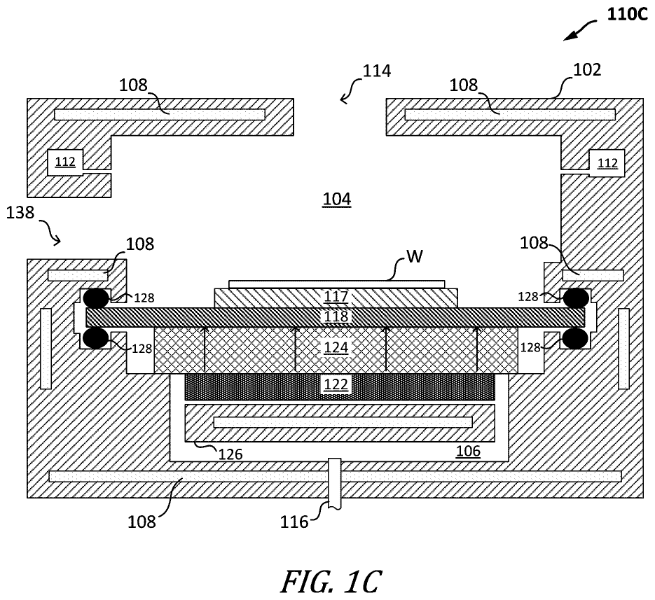

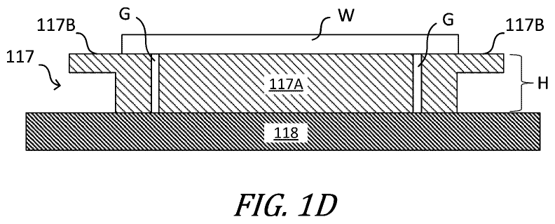

FIG. 1A illustrates one embodiment of a semiconductor processing system 100 including an improved CVD reactor 110A in accordance with the present disclosure, a gas supply system 120 for supplying various gases to the CVD reactor 110A and a controller 130 for controlling various hardware components of the CVD reactor 110A and processing steps performed within CVD reactor 110A.

As shown in FIG. 1A, the CVD reactor 110A includes a double chambered, water-cooled reactor body 102 having an upper process chamber 104 for receiving a semiconductor substrate (or wafer, W) to be processed, and a lower heating chamber 106 for heating the semiconductor substrate W during various processing steps performed on the substrate surface. The reactor body 102 can be formed from a variety of materials, such as stainless steel (e.g., SUS316), aluminum, etc. A water channel 108 is provided within the walls of the reactor body 102 to assist in cooling the upper process chamber 104 and the lower heating chamber 106 after various high temperature processing steps are performed within the upper process chamber 104. Reducing the temperature on the interior walls of the reactor body 102 may also prevent (or at least reduce) material deposition on the reactor body walls.

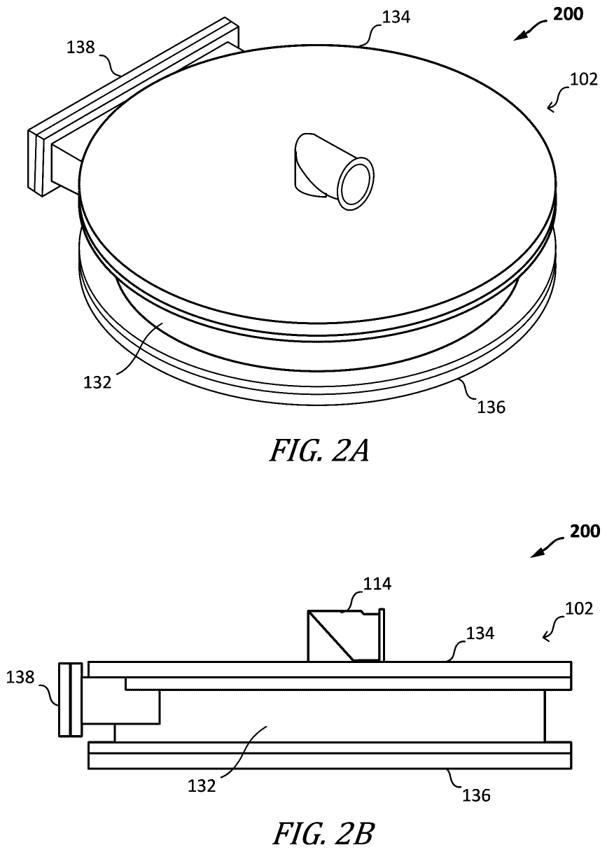

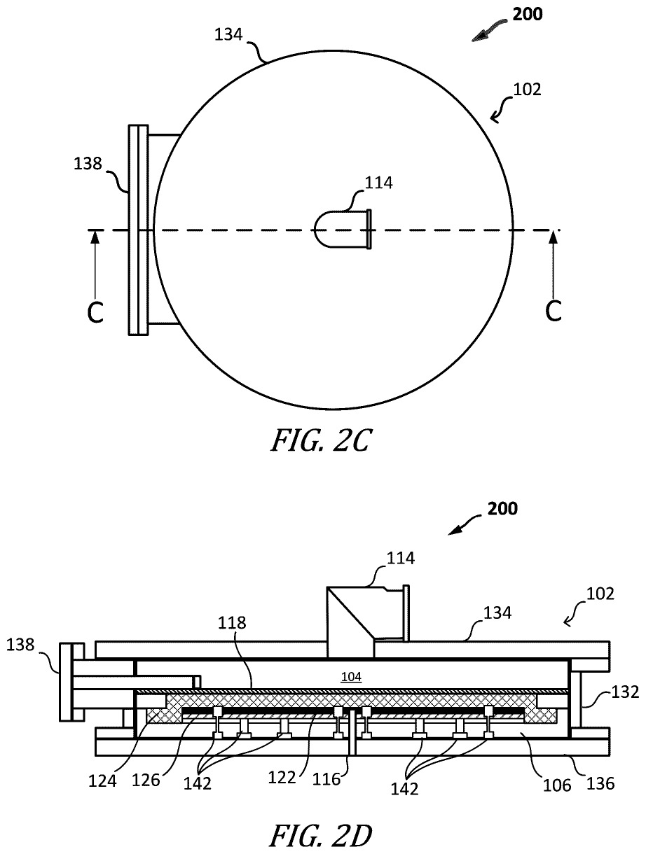

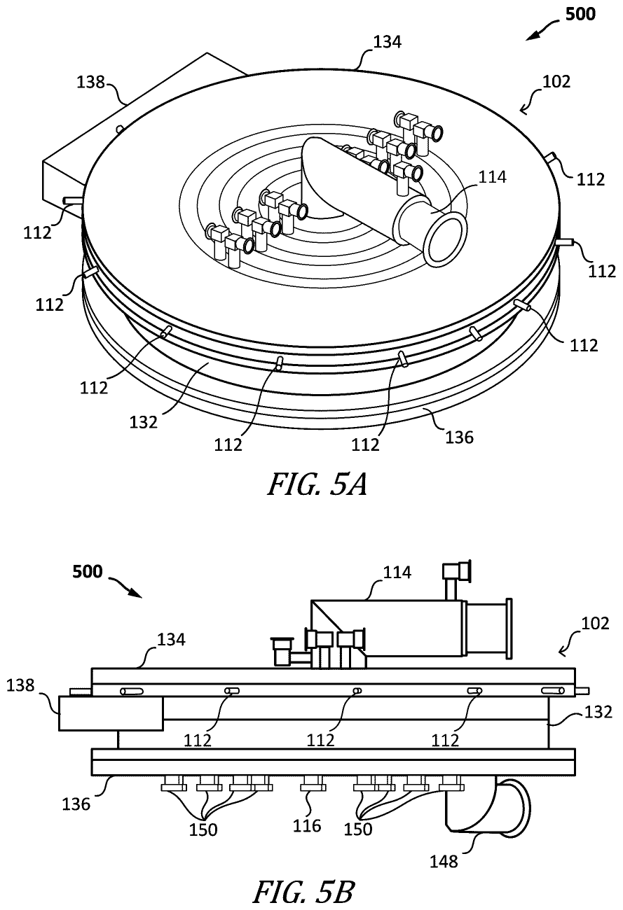

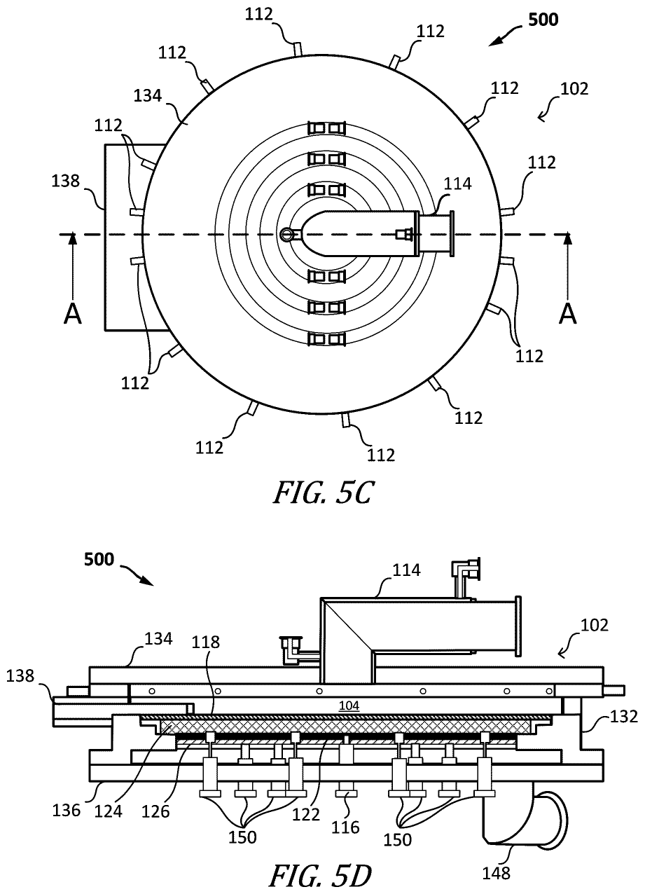

A plurality of gas inlets 112 and a central exhaust port 114 are fluidly coupled to the upper process chamber 104 of the CVD reactor 110A for respectively supplying and removing process gas(es) to/from the upper process chamber 104. The plurality of gas inlets 112 may be distributed around a periphery of the upper process chamber 104 as shown, for example, in the embodiments depicted in FIGS. 5A-5D, FIG. 12 and FIGS. 14A-14B. The central exhaust port 114 is centrally located at (or near) a center point of the water-cooled top plate (not shown in FIG. 1A) of the reactor body 102 as shown, for example, in FIGS. 2A, 2C, 5A and 5C.

During various processing steps, the plurality of gas inlets 112 supply process gas(es) to the upper process chamber 104 to pressurize the upper process chamber 104 and provide uniform process gas flow across the surface of the semiconductor substrate W to the central exhaust port 114. A wide variety of process gas(es) may be supplied to the upper process chamber 104, depending on the process being performed. In some embodiments, a quartz liner 115 may be provided on the interior walls of the upper process chamber 104 to protect the interior walls of the upper process chamber 104 from the process gas(es) supplied to the upper process chamber 104 by the gas inlets 112.

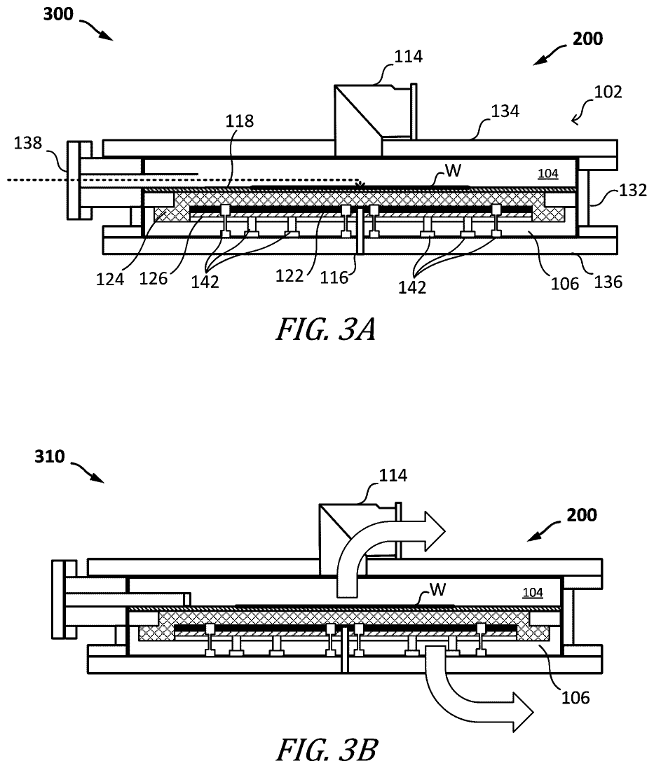

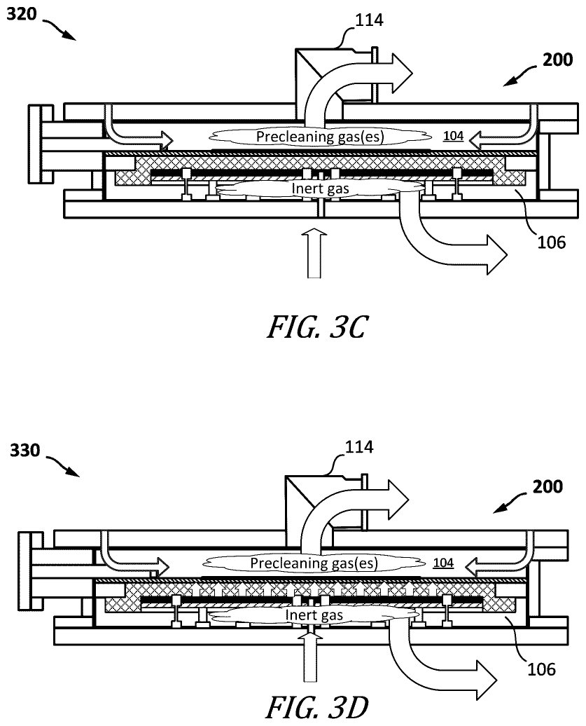

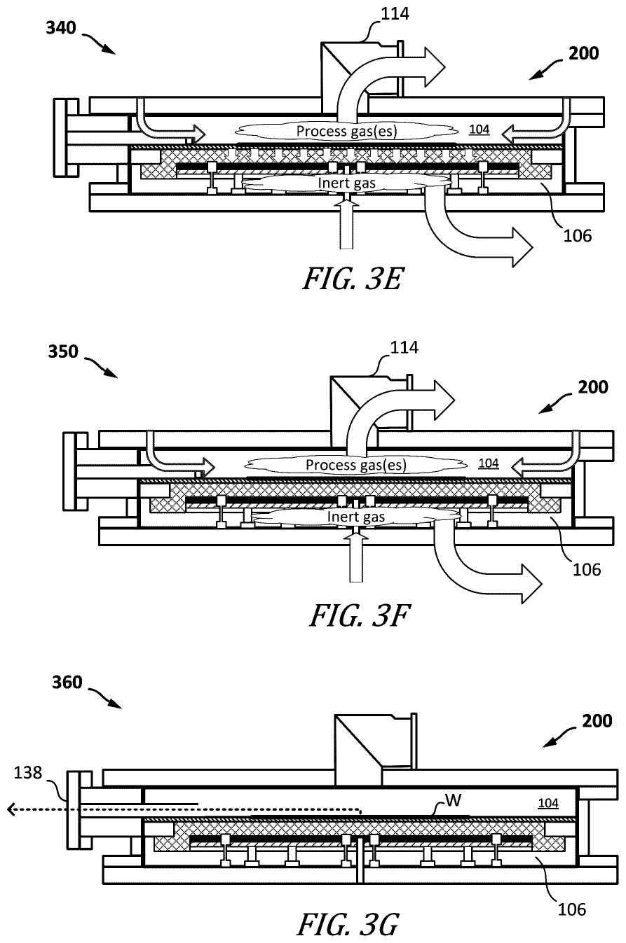

A lower gas inlet 116 and a lower exhaust port (not shown in FIG. 1A) are fluidly coupled to the lower heating chamber 106 of the CVD reactor 110A for respectively supplying and removing an inert gas to/from the lower heating chamber 106. As shown in FIGS. 3A-3G, the lower gas inlet 116 may be centrally located at (or near) a center point of a water-cooled base flange (not shown in FIG. 1A) of the reactor body 102. The lower exhaust port 148, on the other hand, may be located near a periphery of the water cooled base flange 136 as shown, for example, in FIGS. 5B and 5D.

The lower gas inlet 116 supplies an inert gas to the lower heating chamber 106 to pressurize the lower heating chamber 106 during various processing steps performed on the semiconductor substrate W disposed within the upper process chamber 104. A wide variety of inert gases (such as, for example, nitrogen (N₂), argon (Ar), helium (He), etc.) may be supplied to the lower heating chamber 106 to pressurize the lower heating chamber 106. In some embodiments, the lower gas inlet 116 may continue to supply an inert gas to the lower heating chamber 106 after high temperature processing steps are performed within the upper process chamber 104 to further assist in cooling the upper process chamber 104 and the lower heating chamber 106 by flushing heat out of the lower heating chamber 106.

The upper process chamber 104 and the lower heating chamber 106 of the reactor body 102 can be independently pumped, via the central exhaust port 114 and the lower exhaust port 148, to control the pressure within the upper and lower chambers. In some embodiments, the upper process chamber 104 and the lower heating chamber 106 can be independently pumped to equalize the pressure within the upper and lower chambers when depositing material on the substrate surface, as this may improve the material deposition rate and uniformity performance. In other embodiments, the lower heating chamber 106 may be pumped to a lower pressure during the material deposition step.

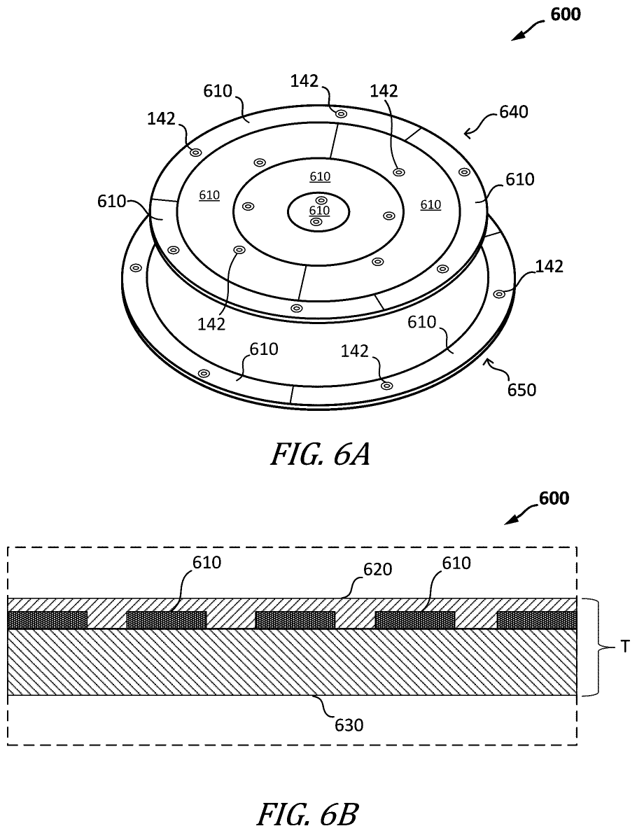

The CVD reactor 110A further includes a susceptor 118 positioned within the upper process chamber 104 and a ceramic resistive heater 122 positioned within the lower heating chamber 106. In one embodiment, the ceramic resistive heater 122 may be a relatively thin, pyrolytic graphite (PG)/pyrolytic boron nitride (PBN) heater, as described in more detail below in reference to FIGS. 6-10. A spring loaded, water-cooled support plate 126 is provided within the lower heating chamber 106 to provide structural support for the ceramic resistive heater 122 and assist in cooling the ceramic resistive heater 122. The water-cooled support plate 126 may be formed from a wide variety of materials, such as stainless steel, quartz or ceramic.

A semiconductor substrate W is received within the upper process chamber 104 and mounted on the susceptor 118 prior to processing the substrate. During various processing steps performed on the substrate surface, the ceramic resistive heater 122 generates heat which is provided to the semiconductor substrate W mounted on the susceptor 118. The upper process chamber 104 and the lower heating chamber 106 are divided by a gasket sealed, conductive heat spreader 124, which is thermally coupled between the ceramic resistive heater 122 and the susceptor 118 to conductively transfer the heat generated by the ceramic resistive heater 122 to the susceptor 118 and the semiconductor substrate W mounted thereon. The conductive heat spreader 124 and the susceptor 118 may each be formed from a wide variety of thermally conductive materials. For example, the conductive heat spreader 124 may be formed from high temperature elements that have good thermal conductance. For example, a metal material with a high melting point and good thermal conductance, such as tungsten (W), chromium (Cr), osmium (Os), etc., or an alloy thereof may be used to form the conductive heat spreader 124. The material chosen for the susceptor 118 should be compatible with the processing environment and have at least some resistance to the dry chemical etching periodically performed to remove deposited films. In some embodiments, materials such as quartz, silicon carbide (SiC), silicon nitride (SiN), graphite (e.g., coated with SiC) may be used to form the susceptor 118. Unlike the conductive heat spreader 124, the material chosen to form the susceptor 118 need not have high thermal conductance. In one example, the conductive heat spreader 124 may be a tungsten (W) heat spreader and the susceptor 118 may be quartz. In some embodiments, a gasket 128 (e.g., a metal seal or an elastomer seal, such as an O-ring) may be provided between the conductive heat spreader 124 and the inner walls of the lower heating chamber 106 to seal the processing spaces within the upper process chamber 104 and the lower heating chamber 106, thereby preventing gases from the upper and lower chambers from mixing.

The conductive heat spreader 124, which is thermally coupled between the ceramic resistive heater 122 and the susceptor 118, enables direct conductive heating of the semiconductor substrate W and provides the uniform heat distribution needed to deposit a layer of material uniformly across the substrate surface. In some embodiments, the conductive heat spreader 124 may provide “uniform heat distribution” by providing less than about 1° C. temperature variation across the substrate surface.

In some embodiments, the conductive heat spreader 124 may be in direct thermal contact with an upper surface of the ceramic resistive heater 122 and a lower surface of the susceptor 118 as shown, for example, in the embodiments depicted in FIGS. 1A-1C, FIG. 2D, FIGS. 3A-3G and FIG. 5D. In such embodiments, the lower surface of the susceptor 118 may cover an upper surface of the conductive heat spreader 124 to protect the conductive heat spreader 124 from the process gas(es) supplied to the upper process chamber 104 during the various processing steps. In some embodiments, a malleable graphite foil (not shown in the figures) may be provided between lower surface of the conductive heat spreader 124 and the upper surface of the ceramic resistive heater 122 to improve thermal conductivity between the ceramic resistive heater 122 and the conductive heat spreader 124.

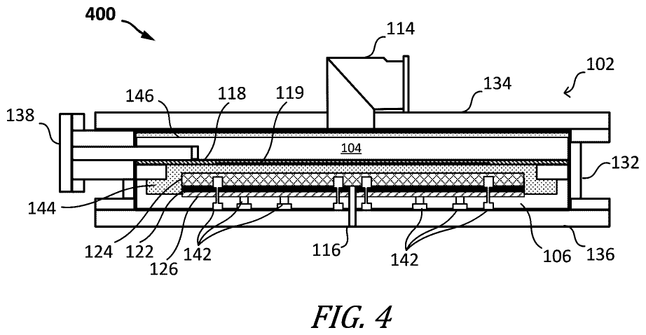

In other embodiments, the conductive heat spreader 124 may be in: (a) direct thermal contact with the upper surface of the ceramic resistive heater 122, and (b) indirect thermal contact with the lower surface of the susceptor 118 as shown, for example, in the embodiment depicted in FIG. 4. In such embodiments, a quartz window 144 may be coupled between the upper surface the conductive heat spreader 124 and the lower surface of the susceptor 118 to conductively and radiatively transfer the heat, which is generated by the ceramic resistive heater 122 and conducted through the conductive heat spreader 124 to the susceptor 118.

FIGS. 1B and 1C illustrate alternative embodiments of a CVD reactor 110B and 110C in accordance with the present disclosure. Many of the reactor components shown in FIG. 1A are also shown in FIGS. 1B and 1C. For example, the CVD reactors 110B and 110C each include a reactor body 102 comprising an upper process chamber 104 and a lower heating chamber 106, as described above. Like the previous embodiments, the interior of the CVD reactors 110B and 110C includes a ceramic resistive heater 122 supported by a water-cooled support plate 126, a conductive heat spreader 124 for conducting and uniformly distributing heat generated by the ceramic resistive heater 122 and a susceptor 118 for transferring the heat uniformly distributed by the conductive heat spreader 124.

The CVD reactors 110B and 110C differ from the embodiment shown in FIG. 1A by providing a pedestal 117 for supporting a semiconductor substrate W and transferring the semiconductor substrate W in and out of the upper process chamber 104 through a loading port 138 coupled to the reactor body 102. Once transferred into the upper process chamber 104, the pedestal 117 (and the semiconductor substrate W mounted thereon) is configured to rest on an upper surface of the susceptor 118 as shown in FIGS. 1B and 1C. Like the conductive heat spreader 124 and the susceptor 118, the pedestal 117 may be formed from a wide variety of thermally conductive materials. For example, the pedestal 117 may be composed of quartz, silicon carbide (SiC), silicon nitride (SiN), graphite (e.g., coated with SiC) or a metal material. Like the susceptor 118, the material chosen to form the pedestal 117: (a) should be compatible with the processing environment, (b) have at least some resistance to the dry chemical etching periodically performed to remove deposited films, and (c) is not required to have high thermal conductivity. In one example, the pedestal 117 may be composed of quartz.

The pedestal 117 shown in FIGS. 1B and 1C provides various advantages. For example, the pedestal 117 transfers the heat, which is generated by the ceramic resistive heater 122 and conducted through the conductive heat spreader 124 and the susceptor 118, to the semiconductor substrate W. As such, the pedestal 117 further improves the heat distribution uniformity across the semiconductor substrate. In addition to smoothing the temperature profile across the substrate surface, the pedestal 117 provides a way for supporting and transporting the semiconductor substrate W in and out of the upper process chamber 104. In doing so, the pedestal 117 eliminates the need to provide lifting pins within the susceptor 118, which may adversely affect the temperature profile across the substrate surface.

A cross-section of an example pedestal 117 design is shown in FIG. 1D. In the example embodiment shown in FIG. 1D, the pedestal 117 comprises two distinct structures: a circular center disk 117A surrounded by an outer annular ring 117B. The circular center disk 117A and the outer annular ring 117B are identical in height (H), so that an upper surface of the circular center disk 117A is flush with the upper surface of the outer annular ring 117B. This ensures that the lower surface of the semiconductor substrate W contacts the upper surface of the circular center disk 117A and the upper surface of the outer annular ring 117B when the substrate is received within the upper process chamber 104 and mounted fully on the pedestal 117.

The circular center disk 117A of the pedestal 117 is fixedly attached to the upper surface of the susceptor 118, and thus, remains within the upper process chamber 104. The outer annular ring 117B, on the other hand, is designed to be transported into and out of the upper process chamber 104 by an effector. For example, the outer annular ring 117B may have a protrusion as shown in FIG. 1D (or an indentation, not shown), which enables an effector (e.g., a gripping type or fork end effector) to grasp and move the outer annular ring 117B of the pedestal 117 into and out of the upper process chamber 104.

When loading a semiconductor substrate W into the upper process chamber 104 utilizing the pedestal 117 design is shown in FIG. 1D, the semiconductor substrate W is initially mounted onto the outer annular ring 117B of the pedestal 117. The outer annular ring 117B having the substrate mounted thereon is then transported by the effector through the loading port 138 of the reactor body 102 into the upper process chamber 104 and positioned onto the circular center disk 117A. Once positioned as shown in FIG. 1D, various processing steps may be performed within the upper process chamber 104 to process the semiconductor substrate W. After substrate processing is complete, the effector may again enter the upper process chamber 104, grasp and lift the outer annular ring 117B off the circular center disk 117A to transport the outer annular ring 117B and the substrate mounted thereon out of the upper process chamber 104. In some embodiments, the circular center disk 117A and the outer annular ring 117B may be separated by a small gap (G, e.g., less than 2 mm) to enable the outer annular ring 117B to be placed onto and lifted off of the circular center disk 117A.

The CVD reactors 110A, 110B and 110C shown in FIGS. 1A-1C enable a uniform thickness of the material to be deposited across the surface of the semiconductor substrate W by at least utilizing: (a) a ceramic resistive heater 122 and a conductive heat spreader 124 to provide uniform heat distribution across the substrate surface during the deposition step, and (b) a plurality of gas inlets 112, which are distributed around a periphery of the upper process chamber 104 to provide uniform gas flow of the process gas(es) across the substrate surface to the central exhaust port 114. Material uniformity and deposition rate is further improved in the CVD reactors 110A, 110B and 110C by separating the upper process chamber 104 from the lower heating chamber 106 and independently pumping and pressurizing the upper and lower chambers, as discussed briefly above. Another novel feature of the CVD reactors 110A, 110B and 110C includes a new ceramic resistive heater 122, which when coupled with the conductive heat spreader 124, provides less than about 1° C. temperature variation across the substrate surface.

The CVD reactors 110A, 110B and 110C shown in FIGS. 1A-1C can be used to deposit a wide variety of materials on a surface of a semiconductor substrate. In some embodiments, the CVD reactors 110A, 110B and 110C may be used to deposit a uniform layer of a silicon-containing material on the substrate surface. Examples of silicon-containing materials that may be deposited using the techniques disclosed herein include, but are not limited to, silicon (Si), poly-silicon (poly-Si), silicon germanium (SiGe), silicon germanium carbide (SiGeC), silicon carbide (SiC), silicon nitride (SiN), silicon carbonitride (SiCN) and silicon carboxide (SiCO). In one example embodiment, the CVD reactors 110A, 110B and 110C may be used to deposit a uniform thickness of silicon germanium (SiGe) across the substrate surface as shown, for example, in the process flow depicted in FIGS. 3A-3G. It is recognized, however, that the CVD reactors 110A, 110B and 110C are not strictly limited to depositing silicon-containing materials and can be used to deposit other materials with uniform deposition rate and thickness across the substrate surface.

As noted briefly above, the semiconductor processing system 100 includes a gas supply system 120 for supplying various gases to one of the CVD reactors 110A, 110B or 110C (hereinafter referred to as CVD reactor 110) and a controller 130 for controlling various hardware components of the CVD reactor 110 and processing steps performed within CVD reactor 110. As shown in FIG. 1A, the gas supply system 120 is coupled to: (a) the plurality of gas inlets 112 for supplying process gas(es) to the upper process chamber 104, and (b) the lower gas inlet 116 for supplying inert gas(es) to the lower heating chamber 106 of the CVD reactor 110. A wide variety of process gas(es) and inert gas(es) may be supplied by the gas supply system 120, depending on the process being performed within the upper process chamber 104.

For example, when depositing silicon germanium (SiGe) on the substrate surface, the gas supply system 120 may supply a combination of silane (SiH₄), germane (GeH₄) and hydrogen (H₂) gases to the upper process chamber 104 of the CVD reactor 110 via the plurality of gas inlets 112. During the SiGe deposition process, the gas supply system 120 may supply an inert gas (such as, for example, nitrogen (N₂), argon (Ar), helium (He), etc.) to the lower heating chamber 106 via the lower gas inlet 116 to equalize the pressure within the upper process chamber 104 and the lower heating chamber 106. In some embodiments, the substrate surface may be cleaned to remove contaminants from the substrate surface prior to deposing SiGe on the substrate surface. When precleaning the substrate surface, the gas supply system 120 may supply a precleaning gas (such as for example, hydrogen (H₂), oxygen (O₂), etc.) to the upper process chamber 104 while supplying an inert gas (such as, for example, nitrogen (N₂), argon (Ar), helium (He), etc.) to the lower heating chamber 106.

Components of the semiconductor processing system 100 can be coupled to, and controlled by, the controller 130, which in turn, can be coupled to a corresponding memory storage unit and user interface (not shown). Various processing operations can be executed via the user interface, and various processing recipes and operations can be stored in the memory storage unit. Accordingly, a given substrate can be processed within the upper process chamber 104 of the CVD reactor 110 in accordance with a particular recipe. In some embodiments, a given substrate can be processed within the upper process chamber 104 in accordance with a process recipe that utilizes the techniques described herein to deposit a uniform layer of material across the substrate surface.

The controller 130 shown in block diagram form in FIG. 1A can be implemented in a wide variety of manners. In one example, the controller 130 may be a computer. In another example, the controller 130 may include one or more programmable integrated circuits that are programmed to provide the functionality described herein. For example, one or more processors (e.g., a microprocessor, microcontroller, central processing unit, etc.), programmable logic devices (e.g., a complex programmable logic device (CPLD), field programmable gate array (FPGA), etc.), and/or other programmable integrated circuits can be programmed with software or other programming instructions to implement the functionality of a prescribed process recipe. It is further noted that the software or other programming instructions can be stored in one or more non-transitory computer-readable mediums (e.g., memory storage devices, flash memory, dynamic random access memory (DRAM), reprogrammable storage devices, hard drives, floppy disks, DVDs, CD-ROMs, etc.), and the software or other programming instructions when executed by the programmable integrated circuits can cause the programmable integrated circuits to perform the processes, functions, and/or capabilities described herein. Other variations could also be implemented.

As shown in FIG. 1A, the controller 130 may be coupled to various components of the semiconductor processing system 100 to receive inputs from, and provide outputs to, the components. For example, the controller 130 may be coupled to the gas supply system 120 for controlling the various gases supplied to the upper process chamber 104 and the lower heating chamber 106, as well as the gas flow rates of the gases supplied to the upper and lower chambers and the pressure within the upper and lower chambers. The controller 130 may also be coupled to the ceramic resistive heater 122 for controlling the temperature of the semiconductor substrate, and a liquid supply system 140 for controlling the water flow through the water-cooled reactor body 102 and the water-cooled support plate 126. The controller 130 may control other processing system components not shown in FIGS. 1A-1C, as is known in the art.

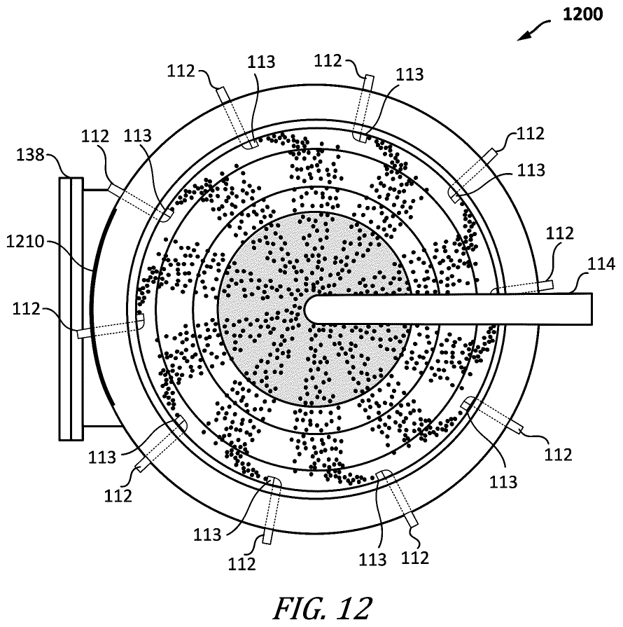

FIGS. 2A-2D illustrate one embodiment of a CVD reactor 200 in accordance with the present disclosure. As shown in FIGS. 2A-2D, the reactor body 102 of the CVD reactor 200 comprises a circular sidewall 132 arranged between a circular water-cooled top plate 134 and a circular water-cooled base flange 136. Like the previous embodiment, the reactor body 102 is a double chambered, water-cooled reactor body having an upper process chamber 104 for receiving a semiconductor substrate (or wafer, W) to be processed, and a lower heating chamber 106 for heating the semiconductor substrate W during various processing steps performed on the substrate surface. As shown in FIG. 2D, the upper process chamber 104 and the lower heating chamber 106 are bound by a lower surface of the circular water-cooled top plate 134, an upper surface of the circular water-cooled base flange 136 and an inner sidewall surface of the circular sidewall 132. Although not readily apparent in FIGS. 2A-2D, the upper process chamber 104 and the lower heating chamber 106 comprise circular inner sidewalls, as shown more clearly in FIG. 12. A loading port 138 is coupled to the reactor body 102 of the CVD reactor 200 for loading a semiconductor substrate into and removing the substrate from the upper process chamber 104 of the CVD reactor 200. A central exhaust port 114 is centrally located at (or near) the center point of the water-cooled top plate 134 of the reactor body 102.

The interior of the CVD reactor 200 is illustrated in FIG. 2D. In the embodiment shown in FIG. 2D, the CVD reactor 200 includes: (i) a susceptor 118 positioned within the upper process chamber 104 for holding a semiconductor substrate, (ii) a ceramic resistive heater 122 positioned within the lower heating chamber 106 for generating heat provided to the semiconductor substrate, (iii) a water-cooled support plate 126 positioned within the lower heating chamber 106 for supporting and cooling the ceramic resistive heater 122, and (iv) a conductive heat spreader 124, which is thermally coupled between the ceramic resistive heater 122 and the susceptor 118 to conductively transfer the heat generated by the ceramic resistive heater 122 to the susceptor 118 and the semiconductor substrate W mounted thereon. In some embodiments, the CVD reactor 200 may further include a pedestal 117 for supporting and transferring the semiconductor substrate W into and out of the upper process chamber 104, as shown in FIGS. 1B-1D.

As shown in FIG. 2D, a plurality of power connectors 142 are provided within the lower heating chamber 106 for supplying power to the ceramic resistive heater 122. The ceramic resistive heater 122 may be a PG/PBN heater, as noted above and described further herein. The power connectors 142 connected to the ceramic resistive heater 122 may be formed from a wide variety of electrically conductive materials. In one embodiment, the power connectors 142 may be formed of tungsten (W). The ceramic resistive heater 122 and the power connectors 142 are discussed in more detail below in reference to FIGS. 6-10.

A wide variety of processes may be performed within the CVD reactor described herein. For example, deposition processes may be performed to deposit material (e.g., a silicon-containing material, a nitrogen-containing material and/or an oxygen-containing material) uniformly across a surface of a semiconductor substrate. In some embodiments, a pre-cleaning process may be performed prior to the deposition process to remove contaminants (such as native oxides or carbon-based contaminants) from the substrate surface.

One embodiment of a process flow that can be performed within the CVD reactor 200 to deposit material uniformly across a surface of a semiconductor substrate W is illustrated in FIGS. 3A-3G. The process flow may generally begin by receiving a semiconductor substrate W through the loading port 138 of the CVD reactor 200 and mounting the substrate onto the susceptor 118 positioned within the upper process chamber 104 of the CVD reactor 200 (in step 300). In some embodiments, a semiconductor substrate W mounted on a pedestal 117 may be received within the loading port 138 and mounted on the susceptor 118, as shown in FIGS. 1B-1D. After the semiconductor substrate W is received within the upper process chamber 104 and the loading port 138 is closed, the upper process chamber 104 and the lower heating chamber 106 may be pumped via the central exhaust port 114 and the lower exhaust port (not shown in FIG. 3B) to a desired base pressure (in step 310).

In some embodiments, an optional precleaning process may be performed in FIGS. 3C and 3D to remove contaminants from the substrate surface prior to depositing material on the substrate surface. The precleaning process may be performed by: (a) suppling one or more precleaning gases to the upper process chamber 104, while inert gas is supplied to the lower heating chamber 106 (in step 320), and (b) heating the semiconductor substrate W to a precleaning temperature (in step 330), which causes the one or more precleaning gases to react with and remove contaminants from the surface of the semiconductor substrate W. The semiconductor substrate W is uniformly heated to the precleaning temperature by the ceramic resistive heater 122 and the conductive heat spreader 124, which conducts the heat generated by the ceramic resistive heater 122 and distributes the heat uniformly across the susceptor 118 and the semiconductor substrate W mounted thereon.

A variety of precleaning gases may be supplied to the upper process chamber 104, depending on the contaminants being removed from the substrate surface. For example, hydrogen (H₂) gas may be supplied to the upper process chamber 104 to remove native oxides and other oxygen-containing contaminants from the substrate surface. When H₂ gas is used to preclean the substrate surface, the precleaning temperature may range between about 700° C. and about 1100° C. In one embodiment, the precleaning temperature may be approximately 850° C. However, other precleaning temperatures may be appropriate when using other precleaning gases to remove other contaminants from the substrate surface.

A material deposition process is performed in step 340 of FIG. 3E. The material deposition process may be performed (in step 340) by: (a) suppling one or more process gases to the upper process chamber 104, while inert gas is supplied to the lower heating chamber 106, and (b) heating the semiconductor substrate W to a material deposition temperature, which decomposes the process gas(es) supplied to the upper process chamber 104 to deposit a material on a surface of the semiconductor substrate. The semiconductor substrate W is uniformly heated to the material deposition temperature by the ceramic resistive heater 122 and the conductive heat spreader 124, which conducts the heat generated by the ceramic resistive heater 122 and distributes the heat uniformly across the susceptor 118 and the semiconductor substrate W mounted thereon.

A variety of process gases may be supplied to the upper process chamber 104, depending on the material being deposited on the substrate surface. In some embodiments, the material deposited in step 340 may be a silicon-containing material. Examples of silicon-containing materials include, but are not limited to, silicon (Si), poly-silicon (poly-Si), silicon germanium (SiGe), silicon germanium carbide (SiGeC), silicon carbide (SiC), silicon nitride (SiN), silicon carbonitride (SiCN) and silicon carboxide (SiCO). The silicon-containing material deposited in step 340 may be undoped or doped with boron (B), phosphorus (P), arsenic (As) or indium (In). When depositing silicon germanium (SiGe) on the substrate surface, for example, a combination of silane (SiH₄), germane (GeH₄) and hydrogen (H₂) gases may be supplied to the upper process chamber 104 (in step 340). During the SiGe deposition process, an inert gas (such as, for example, nitrogen (N₂), argon (Ar), helium (He), etc.) may also be supplied to the lower heating chamber 106 to equalize the pressure within the upper process chamber 104 and the lower heating chamber 106.

The material deposition temperature may be high enough to decompose the process gas(es) supplied to the upper process chamber 104 and deposit the silicon-containing material on the substrate surface. When depositing silicon-containing materials, such as SiGe, the material deposition temperature may be a relatively high temperature ranging between about 500° C. and 900° C. In one embodiment, the material deposition temperature may be approximately 600° C. However, other material deposition temperatures may be appropriate when depositing other materials on the substrate surface. In some embodiments, the substrate may be cooled to the material deposition temperature if a higher temperature precleaning step is performed before the material deposition step.

After material is deposited on the substrate surface, the process flow may cool the semiconductor substrate W to a substantially lower temperature (ranging, e.g., between about 400° C. and 200° C.) in step 350 of FIG. 3F before removing the semiconductor substrate W from the upper process chamber 104 of the CVD reactor 200 in step 360 of FIG. 3G. The substrate may be cooled (in step 350) by turning the ceramic resistive heater 122 off. In some embodiments, the process flow may continue to supply process gas(es) and/or inert gas(es) after the material deposition step to further assist in cooling the substrate by flushing heat out of the upper process chamber 104 and/or the lower heating chamber 106.

FIG. 4 illustrates an alternative embodiment of a CVD reactor 400 in accordance with the present disclosure. Many of the reactor components shown in FIGS. 2A-2D and FIGS. 3A-3G are also shown in FIG. 4. For example, the CVD reactor 400 includes a reactor body 102 an upper process chamber 104, a lower heating chamber 106, and a loading port 138 for loading a semiconductor substrate W into and out of the upper process chamber 104 of the CVD reactor 400, as described above and shown in FIGS. 2A-2D and FIGS. 3A-3G. Like the previous embodiments, the interior of the CVD reactor 400 includes a ceramic resistive heater 122 supported by a water-cooled support plate 126, a conductive heat spreader 124 for conducting and distributing heat generated by the ceramic resistive heater 122 and a susceptor 118 for transferring the heat uniformly distributed by the conductive heat spreader 124. In some embodiments, the susceptor 118 may receive and support a semiconductor substrate W loaded into the upper process chamber 104 via the loading port 138. In other embodiments, the susceptor 118 may receive and support a pedestal 117 having a semiconductor substrate W mounted thereon, as shown in FIGS. 1B-1D.

The CVD reactor 400 shown in FIG. 4 differs from the previous embodiments shown in FIGS. 1-3 by coupling a quartz window 144 between the upper surface the conductive heat spreader 124 and the lower surface of the susceptor 118. In the embodiment shown in FIG. 4, the quartz window 144 conductively and radiatively transfers the heat, which is generated by the ceramic resistive heater 122 and conducted through the conductive heat spreader 124, to the susceptor 118. A temperature sensor 119 is embedded within the susceptor 118 for monitoring temperature conditions within the upper process chamber 104. In one embodiment, the temperature sensor 119 may be a substrate material having a metal pattern formed thereon. The metal pattern may comprise one or more thermocouple junctions for measuring the temperature of the susceptor 118, the temperature of the substrate mounted on the susceptor 118 or the ambient temperature within the upper process chamber 104. The CVD reactor 400 also includes a quartz liner 146 on interior walls of the upper process chamber 104 to protect the interior walls of the upper process chamber 104 from process gas supplied to the upper process chamber 104 during various processing steps.

FIGS. 5A-5D illustrate yet another embodiment of a CVD reactor 500 in accordance with the present disclosure. Like the previous embodiment shown in FIGS. 2A-2D, the reactor body 102 of the CVD reactor 500 includes a circular sidewall 132 arranged between a circular water-cooled top plate 134 and a circular water-cooled base flange 136. A loading port 138 is coupled to the reactor body 102 for loading a semiconductor substrate into and out of the upper process chamber 104 of the CVD reactor 500. A central exhaust port 114 is centrally located at (or near) the center point of the water-cooled top plate 134 of the reactor body 102. In the embodiment shown in FIGS. 5A-5D, the central exhaust port 114 is water cooled to control the temperature of the gases exhausted through the central exhaust port 114. A lower exhaust port 148 is located near a periphery of the water-cooled base flange 136 as shown in FIGS. 5B and 5D.

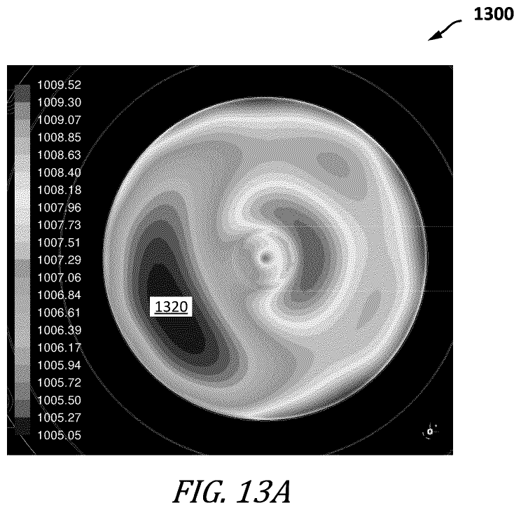

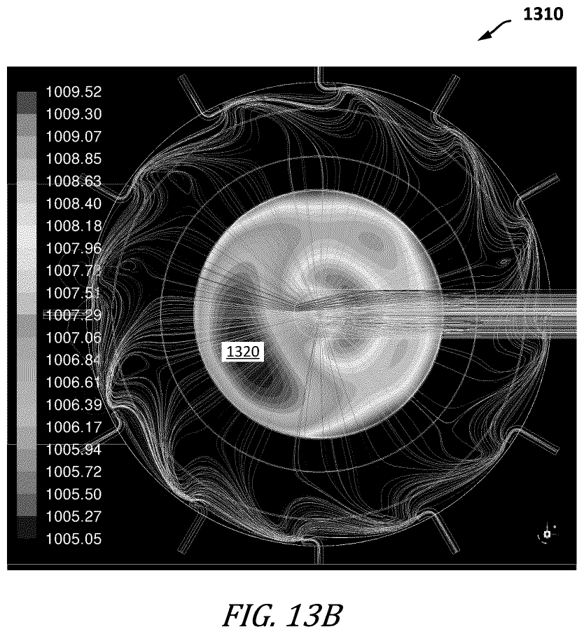

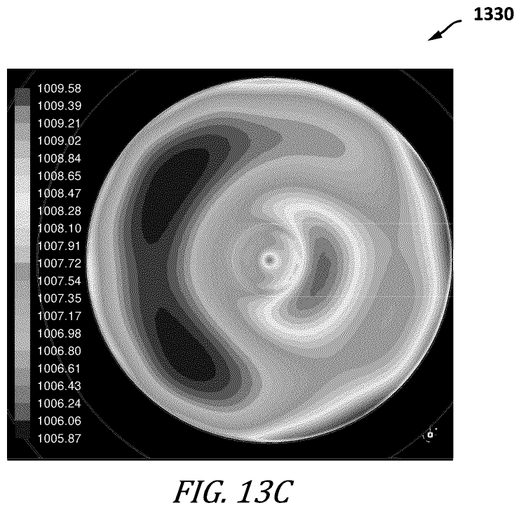

A plurality of gas inlets 112 are distributed around the periphery of the reactor body 102 in the CVD reactor 500 for supplying process gas(es) to the upper process chamber 104. As shown in FIGS. 5A-5D and FIG. 12, the plurality of gas inlets 112 are equally spaced around the circular sidewall 132 of the upper process chamber 104. This enables the gas inlets to direct process gas flow along the circular inner sidewall of the upper process chamber 104 in a clockwise direction or a counter-clockwise direction as shown in FIG. 12 and FIG. 13B and discussed in more detail below.

The interior of the CVD reactor 500 is illustrated in FIG. 5D. In the embodiment shown in FIG. 5D, the CVD reactor 500 includes: (i) a susceptor 118 positioned within the upper process chamber 104 for holding a semiconductor substrate, (ii) a ceramic resistive heater 122 positioned within the lower heating chamber 106 for generating heat provided to the semiconductor substrate, (iii) a water-cooled support plate 126 positioned within the lower heating chamber 106 for supporting and cooling the ceramic resistive heater 122, and (iv) a conductive heat spreader 124, which is thermally coupled between the ceramic resistive heater 122 and the susceptor 118 to conductively transfer the heat generated by the ceramic resistive heater 122 to the susceptor 118 and the semiconductor substrate W mounted thereon. In some embodiments, the CVD reactor 500 may further include a pedestal 117 for supporting and transferring the semiconductor substrate W into and out of the upper process chamber 104, as shown in FIGS. 1B-1D. As noted above and described further herein, a plurality of power connectors 142 are provided within the lower heating chamber 106 for supplying power to the ceramic resistive heater 122. As shown in FIGS. 5B and 5D, a plurality of power feedthroughs 150 are provided within the water-cooled base flange 136. The power feedthroughs 150 extend through the water-cooled base flange 136 to provide power to the power connectors 142 within the lower heating chamber 106.

FIGS. 6-10 provide additional details for the ceramic resistive heater 122 and the power connectors 142 discussed above. As shown in FIGS. 6-10, the ceramic resistive heater 122 is a pyrolytic graphite (PG)/pyrolytic boron nitride (PBN) heater comprising PG resistive heating elements formed above a PBN backplate. The ceramic resistive heater 122 can be implemented as one or more base plates, each having multiple heating zones. Each heating zone within the ceramic resistive heater 122 comprises PG resistive heating elements and at least two power connectors 142 for supplying current to the PG resistive heating elements within that heating zone. In this manner, the temperature within each heating zone can be independently controlled by independently controlling the amount of current supplied to the PG resistive heating elements included within each heating zone.

The PG/PBN heater shown in FIGS. 6-10 is a preferred heating source for the deposition processes described herein, due to its ability to dynamically heat at rapid ramp rates (e.g., about 200° C. or more per minute) with high power density. In some embodiments, the PG/PBN heater shown in FIGS. 6-10 may rapidly heat a substrate surface from room temperature to about 800° C. in about 3 minutes. The PG/PBN heater shown in FIGS. 6-10 may also be quickly cooled, due to its minimal thickness. In one embodiment, the thickness (T) of the PG/PBN heater shown in FIGS. 6-10 may be less than about 2 nm.

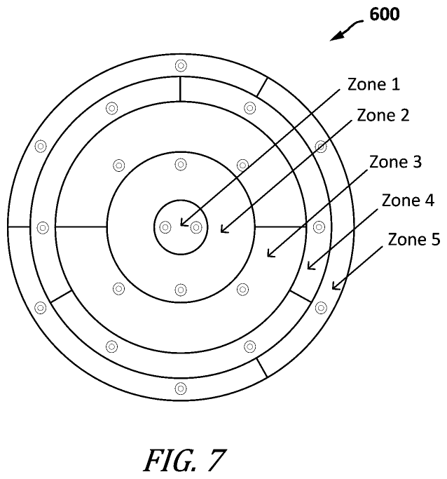

FIGS. 6A-6B illustrate one embodiment of a ceramic resistive heater 600 in accordance with the present disclosure. In the embodiment shown in FIGS. 6A-6B, the ceramic resistive heater 600 includes two base plates, each having multiple heating zones. Specifically, the ceramic resistive heater 600 includes: (i) a 380 mm (outer diameter, OD) circular inner heater base plate 640 having seven (7) PG resistive heating elements 610, and (ii) a 440 mm (OD) annular outer heater base plate 650 having three (3) additional PG resistive heating elements 610. As such, the ceramic resistive heater 600 includes a total of ten (10) PG resistive heating elements 610 divided amongst five (5) annual heating zones as shown and described in reference to FIG. 7.

Each heating zone within the ceramic resistive heater 600 comprises a subset of the PG resistive heating elements 610 and at least two power connectors 142 for supplying current to the subset of PG resistive heating elements included within that heating zone. A cross-section of the ceramic resistive heater 600 is shown in FIG. 6B. As shown in FIG. 6B, the PG resistive heating elements 610 of the ceramic resistive heater 600 are formed between a PBN upper layer 620 and a PBN backplate 630. In one example embodiment, the ceramic resistive heater 600 may comprise a 55μm thick PG resistive heating elements 610 layer and a 100 μm thick PBN upper layer 620. The PG resistive heating elements 610 layer and the PBN upper layer 620 may be formed on a 1.85 mm PBN backplate 630 for a total thickness (T) of less than 2 nm.

FIG. 7 illustrates the multiple heating zones of the ceramic resistive heater 600 shown in FIGS. 6A-6B. As noted above and shown in FIG. 7, the ceramic resistive heater 600 includes five (5) annular heating zones (Zones 1-5), each comprising PG resistive heating elements and power connectors coupled thereto. In particular, the ceramic resistive heater 600 includes: (i) one PG resistive heating element and two power connectors in Zones 1 and 2, (ii) two PG resistive heating elements and four power connectors in Zone 3, and (iii) three PG resistive heating elements and six power connectors in Zones 4 and 5. As such, the ceramic resistive heater 600 shown in FIGS. 6A, 6B and 7 provides uniform heat distribution across the surface of a 300 mm semiconductor substrate by providing less than 1° C. temperature variation across the innermost zones (Zones 1-3).

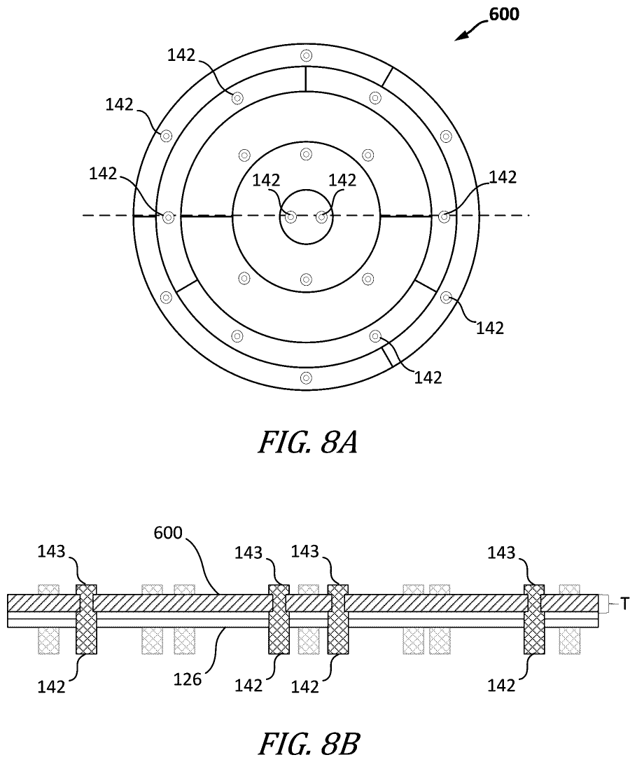

FIGS. 8A-8B illustrate a top view and a cross-sectional view through the ceramic resistive heater 600 shown in FIGS. 6A-6B. As shown in FIG. 2D, FIG. 5D, FIG. 6A and FIGS. 8A-8B, the power connectors 142 electrically coupled to the PG resistive heating elements 610 extend through the water-cooled support plate 126 and the entire thickness (T) of the ceramic resistive heater 600, such that a terminal end 143 of the power connectors 142 is exposed on the upper surface of the ceramic resistive heater 600. In some cases, the terminal end 143 of the power connectors 142 may create cool points on the upper heating surface of the ceramic resistive heater 600, which may affect the temperature uniformity provided thereby.

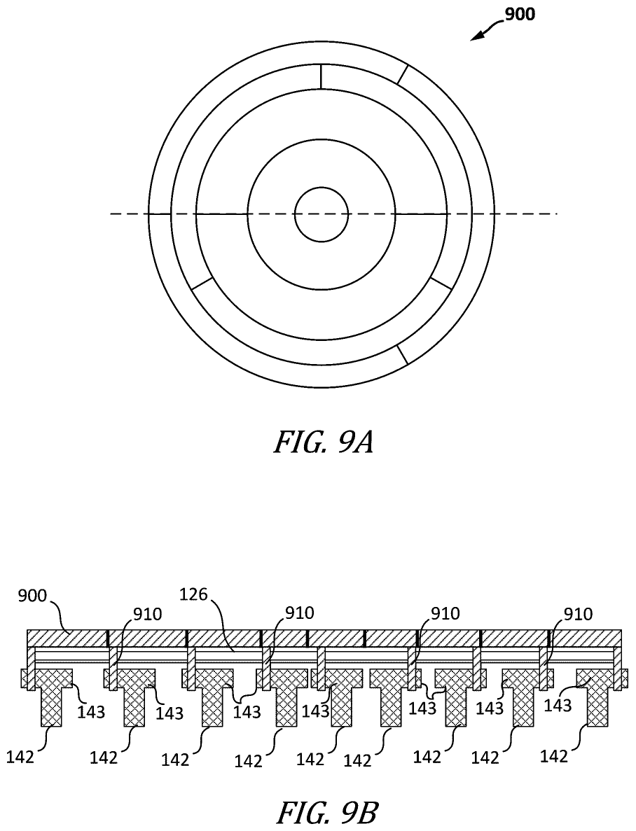

One approach to minimizing temperature non-uniformity across the heating surface of the ceramic resistive heater 600 is to connect the terminal end 143 of the power connectors 142 to the PG resistive heating elements 610 below the lower surface of the ceramic resistive heater 600 to avoid interfering with the upper heating surface. FIGS. 9A-9B illustrate a top view and a cross-sectional view through an alternative embodiment of a ceramic resistive heater 900 having power connectors 142 that electrically connect to the electrically coupled to the PG resistive heating elements 610 of the ceramic resistive heater 900 below the water-cooled support plate 126, so as not to interfere with the upper heating surface of the ceramic resistive heater 900. As shown in FIG. 9B, the terminal end 143 of the power connectors 142 may be electrically coupled to the PG resistive heating elements 610 through electrical connection legs 910, which extend below a lower surface of the ceramic resistive heater 900 through the water-cooled support plate 126 to the power connectors 142.

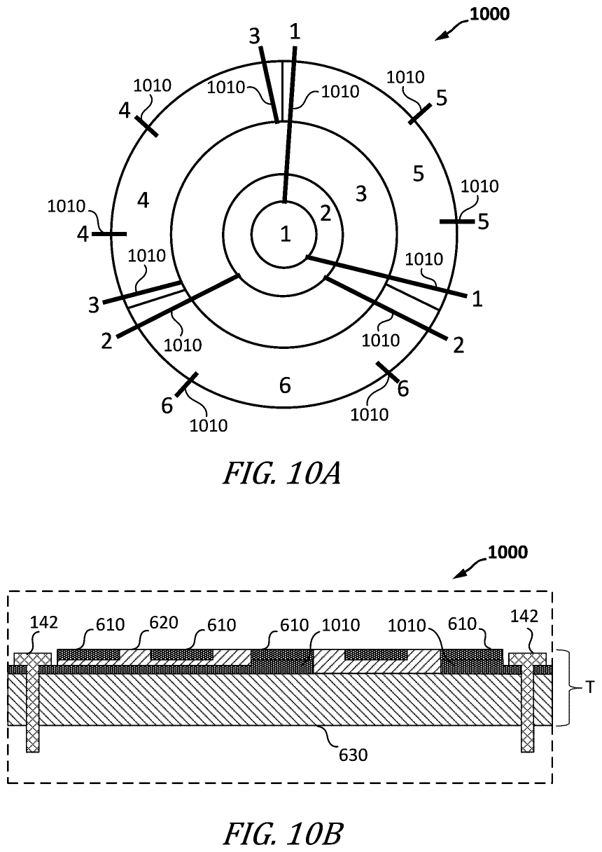

Another approach to minimizing temperature non-uniformity across the heating surface of the ceramic resistive heater 600 is to move the heater connection points outside of the substrate edge. FIGS. 10A-10B illustrate a top view and a cross-sectional view through an alternative embodiment of a ceramic resistive heater 1000 having multiple heating zones, where the electrical connections to each heating zone are arranged peripherally around a circumference of the ceramic resistive heater 1000.

The ceramic resistive heater 1000 shown in FIGS. 10A-10B includes six (6) heating zones (Zones 1-6). Each heating zone within the ceramic resistive heater 1000 comprises a subset of the PG resistive heating elements 610 and at least two power connectors 142 for supplying current to the subset of PG resistive heating elements included within that heating zone. The power connectors 142 connected to each heating zone are labeled 1-6 in FIG. 10A. Like the previous embodiment shown in FIG. 6B, the PG resistive heating elements 610 of the ceramic resistive heater 1000 are formed between a PBN upper layer 620 and a PBN backplate 630. Unlike the previous embodiment, however, the power connectors 142 are peripherally arranged around a circumference of the ceramic resistive heater 1000 in FIGS. 10A-10B to avoid interfering with the upper heating surface of the ceramic resistive heater 1000. By moving the power connectors 142 beyond the circumference of the ceramic resistive heater 1000, and thus outside of the substrate edge, the embodiment shown in FIGS. 10A-10B improves substrate temperature uniformity by preventing the formation of cool points on the upper heating surface of the ceramic resistive heater 1000.

As shown in FIGS. 10A and 10B, each of the power connectors 142 are electrically connected to a corresponding one of the PG resistive heating elements 610 through a PG interconnect 1010. As shown in FIG. 10B, the PG interconnects 1010 are formed on the PBN backplate 630 below the PG resistive heating element 610 layer. In one example embodiment, the ceramic resistive heater 1000 may comprise a 110 μm thick PG interconnects 1010 layer, a 55 μm thick PG resistive heating elements 610 layer and a 100 μm thick PBN upper layer 620, all of which are formed on a 1.85 mm PBN backplate 630 for a total thickness (T) of less than 2 nm.

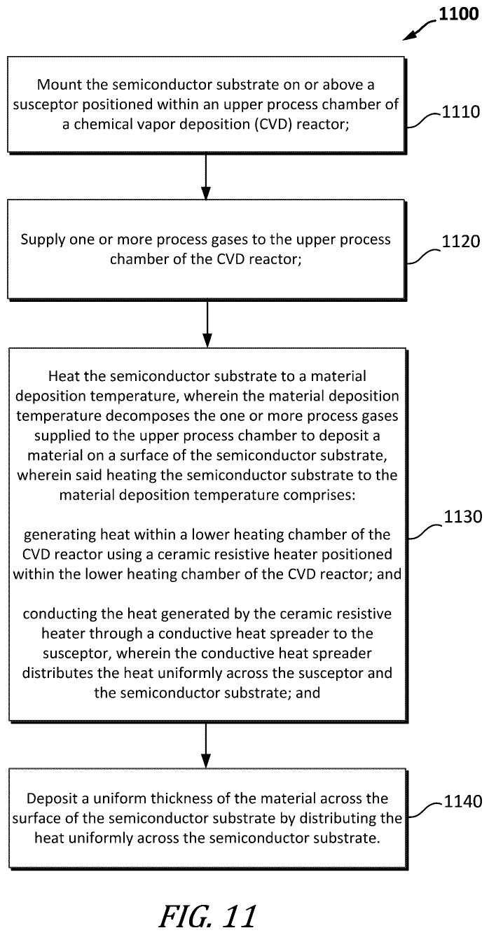

FIG. 11 illustrates one embodiment of a method 1100 that utilizes the techniques disclosed herein to deposit material on a semiconductor substrate using a chemical vapor deposition (CVD) process. The method 1100 may be generally be performed within a CVD reactor as shown and described herein. It will be recognized, however, that the method 1100 is merely exemplary and additional methods may utilize the techniques disclosed herein. Further, additional processing steps may be added to the method 1100 as the steps described are not intended to be exclusive. Moreover, the order of the steps is not limited to the order shown in the figures as different orders may occur and/or various steps may be performed in combination or at the same time.

As shown in FIG. 11, the method 1100 may begin by mounting the semiconductor substrate on a susceptor positioned within an upper process chamber of a chemical vapor deposition (CVD) reactor (in step 1110). In some embodiments, the semiconductor substrate may be loaded into the upper process chamber and mounted directly on the susceptor positioned within an upper process chamber as shown, for example, in FIGS. 1A and 3A-3G. In other embodiments, the semiconductor substrate may be mounted onto a pedestal, which is loaded into the upper process chamber and mounted directly on the susceptor positioned within the upper process chamber as shown, for example, in FIGS. 1B-1D. In such embodiments, the pedestal may be configured to: (a) support the semiconductor substrate, (b) transfer the semiconductor substrate into and out of the upper process chamber, and (c) transfer heat between the susceptor and the semiconductor substrate.

The method 1100 may further include supplying one or more process gases to the upper process chamber of the CVD reactor (in step 1120) and heating the semiconductor substrate to a material deposition temperature (in step 1130). A wide variety of process gas(es) may be supplied to the upper process chamber of the CVD reactor in step 1120. In one embodiment, the one or more process gases supplied to the upper process chamber in step 1120 may comprise a silicon-containing gas. When the semiconductor substrate is heated in step 1130, the material deposition temperature decomposes the one or more process gases supplied to the upper process chamber to deposit a material (such as, e.g., a silicon-containing material) on a surface of the semiconductor substrate. The method 1100 further includes depositing a uniform thickness of the material across the surface of the semiconductor substrate by distributing heat uniformly across the semiconductor substrate (in step 1140).

In the method 1100 shown in FIG. 11, the semiconductor substrate is heated in step 1130 by: (a) generating heat within a lower heating chamber of the CVD reactor using a ceramic resistive heater positioned within the lower heating chamber of the CVD reactor, and (b) conducting the heat generated by the ceramic resistive heater through a conductive heat spreader to the susceptor. The conductive heat spreader distributes the heat generated by the ceramic resistive heater uniformly across the susceptor and the semiconductor substrate mounted thereon. This uniform heat distribution enables the method 1100 to deposit the uniform thickness of the material across the substrate surface (in step 1140).

The method 1100 may be used to deposit a wide variety of materials on the substrate surface. For example, the method 1100 may be used to deposit a silicon-containing material, a nitrogen-containing material and/or an oxygen-containing material on the substrate surface. In some embodiments of the method 1100, a silicon-containing material may be deposited onto the substrate surface by supplying at least one silicon-containing gas to the upper process chamber in step 1120. Examples of silicon-containing materials that may be deposited on the substrate surface (in step 1140) include, but are not limited to, silicon (Si), poly-silicon (poly-Si), silicon germanium (SiGe), silicon germanium carbide (SiGeC), silicon carbide (SiC), silicon nitride (SiN), silicon carbonitride (SiCN) and silicon carboxide (SiCO). The silicon-containing material deposited in step 1140 may be undoped or doped with boron (B), phosphorus (P), arsenic (As) or indium (In). When depositing silicon germanium (SiGe) on the substrate surface, for example, a combination of silane (SiH₄), germane (GeH₄) and hydrogen (H₂) gases may be supplied to the upper process chamber (in step 1120). When depositing silicon-containing materials, such as SiGe, the semiconductor substrate may be heated (in step 1130) to a relatively high material deposition temperature ranging, for example, between about 500° C. and 900° C. In one embodiment, the material deposition temperature used in step 1130 may be approximately 600° C. In some embodiments, the method 1100 may further include cooling the semiconductor substrate to a lower temperature within a range of about 400° C. to 200° C. before removing the semiconductor substrate from the upper process chamber of the CVD reactor.

In some embodiments, the method 1100 may perform one or more additional processing steps before supplying the process gas(es) to the upper process chamber of the CVD reactor (in step 1120). For example, the method 1100 may further include precleaning the surface of the semiconductor substrate by supplying one or more precleaning gases to the upper process chamber of the CVD reactor and heating the semiconductor substrate to a precleaning temperature, which causes the one or more precleaning gases to react with and remove contaminants from the surface of the semiconductor substrate. As in the material deposition step, the semiconductor substrate may be heated to the precleaning temperature by: (a) generating heat within the lower heating chamber of the CVD reactor using the ceramic resistive heater positioned within the lower heating chamber of the CVD reactor, and (b) conducting the heat generated by the ceramic resistive heater through the conductive heat spreader to the susceptor. Because the conductive heat spreader distributes the heat uniformly across the susceptor and the semiconductor substrate mounted thereon during the precleaning step, the precleaning gases remove surface contaminants uniformly across the surface of the semiconductor substrate.

A variety of precleaning gases may be used during the precleaning step, depending on the contaminants being removed from the substrate surface. For example, hydrogen (H₂) gas may be supplied to the upper process chamber to remove native oxides and other oxygen-containing contaminants from the substrate surface. When H₂ gas is used to preclean the substrate surface, the precleaning temperature may range between about 700° C. and about 1100° C. In one embodiment, the precleaning temperature may be approximately 850° C. However, other precleaning temperatures may be appropriate when using other precleaning gases to remove other contaminants from the substrate surface.

In addition to providing uniform substrate temperature, the improved CVD reactor and methods disclosed herein use a novel gas distribution technique to improve material deposition uniformity. Unlike conventional gas distribution techniques, which direct gas flow laterally across a substrate surface, the improved CVD reactor and methods disclosed herein use a plurality of gas inlets distributed around a periphery of the upper process chamber to provide uniform gas flow across the substrate surface to a central exhaust port coupled to the upper process chamber. By providing uniform heat distribution and uniform gas flow across the substrate surface, the improved CVD reactor and methods disclosed herein further improve the uniformity of the material to be deposited across the surface of the semiconductor substrate.

FIG. 12 illustrates one embodiment of a CVD reactor 1200, which uses a gas distribution system designed to provide uniform gas flow across a substrate surface to a central exhaust port. The CVD reactor 1200 shown in FIG. 12 includes many of the same components shown in FIGS. 1-10 such as, but not limited to: (i) a reactor body 102 having a circular sidewall 132 arranged between a circular water-cooled top plate 134 (not shown) and a circular water-cooled base flange 136 (not shown), (ii) a loading port 138 coupled to the reactor body 102 for loading a semiconductor substrate into and out of the upper process chamber 104 of the CVD reactor 1200, (iii) a central exhaust port 114 centrally located at (or near) the center point of the water-cooled top plate 134 of the reactor body 102, and (iv) a plurality of gas inlets 112 distributed around the periphery of the reactor body 102 for supplying process gas(es) to the upper process chamber 104.

In the embodiment shown in FIG. 12, the CVD reactor 1200 includes twelve (12) gas inlets 112. The plurality of gas inlets 112 are equally spaced around the circular sidewall 132 of the upper process chamber 104 and have a distal end 113, which is bent at approximately 75-90° and angled toward the circular inner sidewall of the upper process chamber 104 to direct process gas flow in a clockwise direction (or a counter-clockwise direction) along the circular inner sidewall of the upper process chamber 104 as shown in FIG. 12 and FIG. 13B. The process gas(es) flowing through the upper process chamber 104 are exhausted through the central exhaust port 114. By exhausting the process gas(es) through the central exhaust port 114, the gas flow is redirected radially across the surface of the semiconductor substrate W to provide uniform gas flow of the process gas(es) across the surface of the semiconductor substrate W.

FIG. 13A depicts simulation results 1300 obtained from an example silicon germanium (SiGe) CVD process and illustrates example deposition rate contours of SiGe, which may be deposited across the substrate surface (expressed in angstroms per minute, Å/min) using the gas distribution system shown in FIG. 12. The simulation results 1300 assume an average substrate temperature of about 580° C., a chamber pressure of 1 Torr, a silane (SiH₄) gas flow rate of 1058.8 standard cubic centimeters per minute (sccm), a germane (GeH₄) gas flow rate of 44.1 sccm, and a hydrogen (H₂) gas flow rate of 397.1 sccm. As shown in FIG. 13A, the CVD process deposited a SiGe layer on the substrate surface at an average deposition rate of about 1000 angstroms per minute (Å/min) with an across substrate deviation of approximately 4.5 Å.

The simulation results 1310 shown in FIG. 13B show the gas flow path lines from the gas distribution system shown in FIG. 12 overset on the deposition rate contours shown in FIG. 13A. As shown in FIG. 13B, the gas flow path is initially directed circumferentially around the circular inner sidewall of the upper process chamber 104 in a clockwise direction before the gas flow is redirected radially across the surface of the semiconductor substrate W to the central exhaust port 114. The depressed deposition region 1320 shown in FIGS. 13A and 13B is due to the reticulation cell in the loading area (shown on the left side of the figure). This depressed deposition region 1320 may be reduced, in some embodiments, by adding a moveable shutter 1210 to the loading port 138 to seal the upper process chamber 104, as shown in FIG. 12. The moveable shutter 1210 is opened to receive a semiconductor substrate W within the upper process chamber 104 and closed prior to supplying process gas(es) to the upper process chamber 104. As shown in FIG. 12, the moveable shutter 1210 is flush with the circular inner sidewall of the upper process chamber 104 so as not to create eddies in the process gas flow.

The simulation results 1330 shown in FIG. 13C illustrate the deposition rate contours of SiGe deposited across the substrate surface (expressed in angstroms per minute, Å/min) using the gas distribution system shown in FIG. 12 when the moveable shutter 1210 is closed to seal the upper process chamber 104. The simulation results assume an average substrate temperature of about 580° C., a chamber pressure of 1 Torr, a silane (SiH₄) gas flow rate of 1058.8 standard cubic centimeters per minute (sccm), a germane (GeH₄) gas flow rate of 44.1 sccm, and a hydrogen (H₂) gas flow rate of 397.1 sccm. As shown in FIG. 13C, the CVD process deposited a SiGe layer on the substrate surface at an average deposition rate of about 1000 angstroms per minute (Å/min) with an across substrate deviation of approximately 3.71 Å.

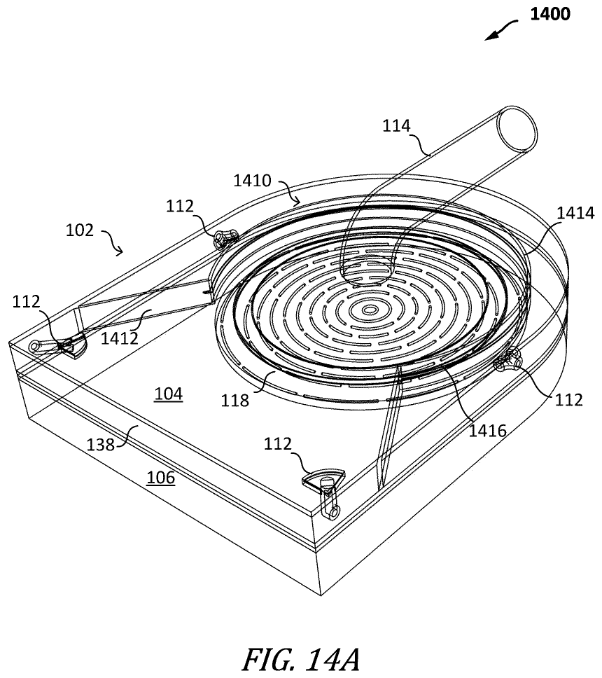

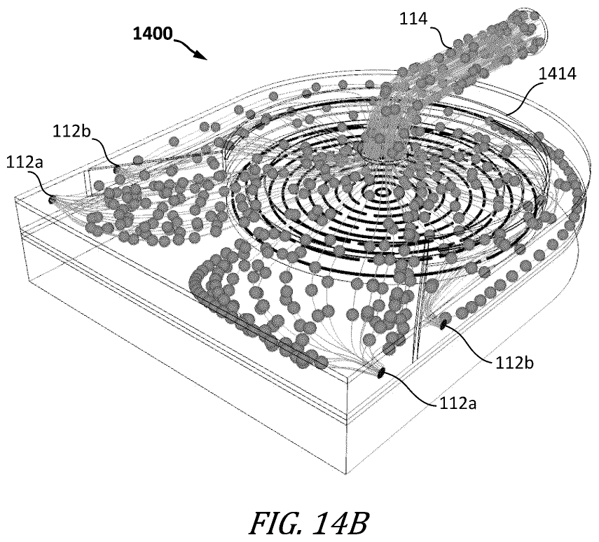

FIGS. 14A-14B illustrate another embodiment of a CVD reactor 1400, which uses a gas distribution system designed to provide uniform gas flow across a substrate surface to a central exhaust port. The CVD reactor 1400 shown in FIGS. 14A-14B includes many of the same components shown in FIGS. 1-10. For example, the CVD reactor 1400 includes: (i) a reactor body 102 comprising an upper process chamber 104 and a lower heating chamber 106, (ii) a loading port 138 coupled to the reactor body 102 for loading a semiconductor substrate into and out of the upper process chamber 104 of the CVD reactor 1400, (iii) a central exhaust port 114 centrally located at (or near) the center point of the water-cooled top plate 134 (not shown) of the reactor body 102, and (iv) a plurality of gas inlets 112 distributed around the periphery of the reactor body 102 for supplying process gas(es) to the upper process chamber 104.

Unlike the previous embodiments, the upper process chamber 104 and the lower heating chamber 106 shown in FIG. 14A each comprise U-shaped inner sidewalls. A gas flow plenum 1410 is provided within the upper process chamber 104 of the CVD reactor 1400. The gas flow plenum 1410 includes an angled lower portion 1412 coupled to a circular upper portion 1414. The circular upper portion 1414 of the gas flow plenum 1410: (a) partially surrounds the susceptor 118 upon which the semiconductor substrate W is mounted, and (b) comprises a gas flow slit 1416.

In the embodiment shown in FIG. 14A, the CVD reactor 1400 includes four (4) gas inlets 112 positioned along the U-shaped inner sidewall of the upper process chamber 104. A first set of gas inlets 112a arranged near the loading port 138 is configured to direct the process gas flow to the angled lower portion 1412 of the gas flow plenum 1410. A second set of gas inlets 112b arranged near the circular upper portion 1414 of the gas flow plenum 1410 is configured to direct the process gas flow around the circular upper portion 1414 and through the gas flow slit 1416 of the circular upper portion 1414 to the semiconductor substrate W.

FIG. 14B is a top view of the CVD reactor 1400 shown in FIG. 14A, illustrating the velocity and direction of gas flow provided across the substrate surface by the new gas distribution system. As shown in FIG. 14B, the flared end of the first set of gas inlets 112a distributes the process gas flow across an acute arc. The angled lower portion 1412 of the gas flow plenum 1410 directs the process gas flow from the first set of gas inlets 112a to semiconductor substrate W. The gas flow from the second set of gas inlets 112b is directed around the circular upper portion 1414 and through the gas flow slit 1416 of the circular upper portion 1414 to the semiconductor substrate W. By exhausting the process gases through the central exhaust port 114, the gas flow from the from the first set of gas inlets 112a and the second set of gas inlets 112b is redirected radially across the surface of the semiconductor substrate W to provide uniform gas flow of the process gas(es) across the surface of the semiconductor substrate W.

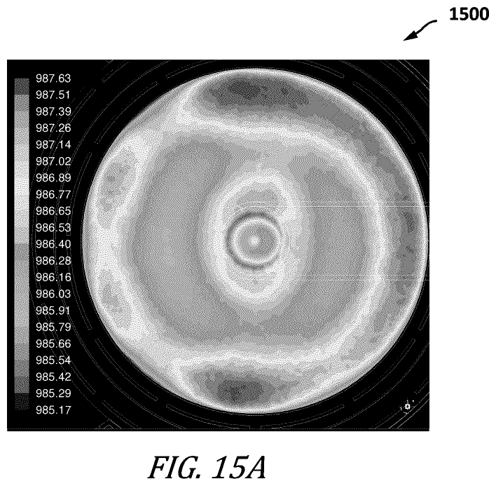

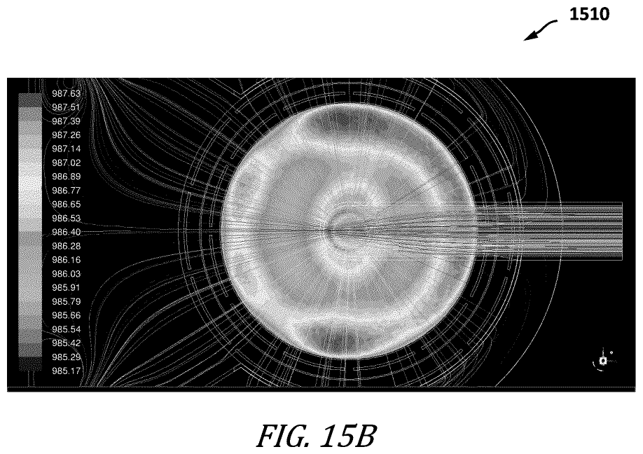

FIG. 15A depicts simulation results 1500 obtained from an example silicon germanium (SiGe) CVD process and illustrates example deposition rate contours of SiGe, which may be deposited across the substrate surface (expressed in angstroms per minute, Å/min) using the gas distribution system shown in FIGS. 14A-14B. The simulation results assume an average substrate temperature of about 580° C., a chamber pressure of 1 Torr, a silane (SiH₄) gas flow rate of 1058.8 standard cubic centimeters per minute (sccm), a germane (GeH₄) gas flow rate of 44.1 sccm, a hydrogen (H₂) gas flow rate of 397.1 sccm and a gas split between the first set of gas inlets 112a and the second set of gas inlets 112b of 29%/71%. As shown in FIG. 15A, the CVD process deposited a SiGe layer on the substrate surface at an average deposition rate of about 1000 angstroms per minute (Å/min) with an across substrate deviation of approximately 2.6 Å.

The simulation results 1510 shown in FIG. 15B depict the gas flow path lines from the gas distribution system shown in FIG. 14A overset on the deposition rate contours shown in FIG. 15A. As shown in FIG. 15B, the gas flow path from the first set of gas inlets 112a is directed approximately radially across the semiconductor substrate W to the central exhaust port 114. The gas flow path from the second set of gas inlets 112b is initially directed circumferentially around the circular upper portion 1414 of the gas flow plenum 1410 before the gas flow is redirected through the gas flow slit 1416 radially across the surface of the semiconductor substrate W to the central exhaust port 114.

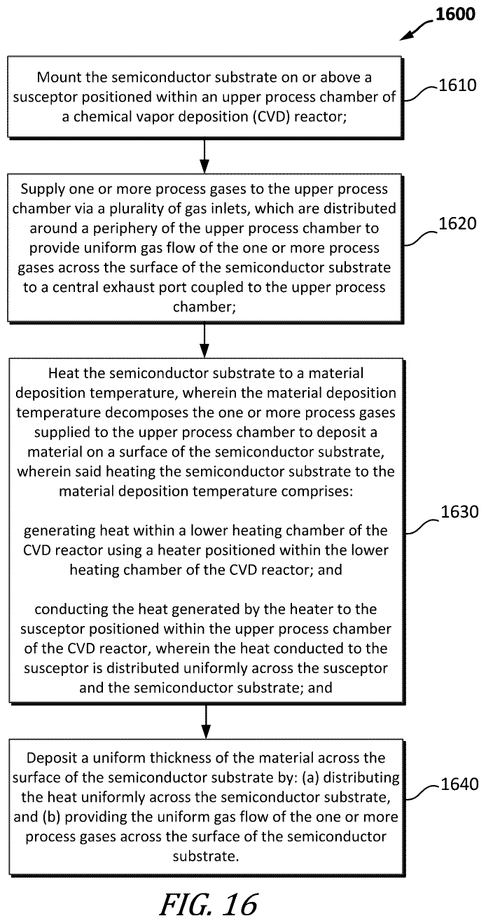

FIG. 16 illustrates one embodiment of a method 1600 that utilizes the techniques described herein to deposit material on a semiconductor substrate using a chemical vapor deposition (CVD) process. The method 1600 may be generally be performed within a CVD reactor as shown and described herein. It will be recognized, however, that the method 1600 is merely exemplary and additional methods may utilize the techniques disclosed herein. Further, additional processing steps may be added to the method 1600 as the steps described are not intended to be exclusive. Moreover, the order of the steps is not limited to the order shown in the figures as different orders may occur and/or various steps may be performed in combination or at the same time.

As shown in FIG. 16, the method 1600 may begin by mounting the semiconductor substrate on or above a susceptor positioned within an upper process chamber of a chemical vapor deposition (CVD) reactor (in step 1610). In some embodiments, the semiconductor substrate may be loaded into the upper process chamber and mounted directly on the susceptor positioned within an upper process chamber as shown, for example, in FIGS. 1A and 3A-3G. In other embodiments, the semiconductor substrate may be mounted onto a pedestal, which is loaded into the upper process chamber and mounted directly on the susceptor positioned within the upper process chamber as shown, for example, in FIGS. 1B-1D. In such embodiments, the pedestal may be configured to: (a) support the semiconductor substrate, (b) transfer the semiconductor substrate into and out of the upper process chamber, and (c) transfer heat between the susceptor and the semiconductor substrate.

The method 1600 further includes supplying one or more process gases via a plurality of gas inlets, which are distributed around a periphery of the upper process chamber to provide uniform gas flow of the one or more process gases across the surface of the semiconductor substrate to a central exhaust port coupled to the upper process chamber (in step 1620). A wide variety of process gas(es) may be supplied to the upper process chamber of the CVD reactor in step 1620. In one embodiment, the one or more process gases supplied to the upper process chamber in step 1620 may comprise a silicon-containing gas.

The method 1600 further includes heating the semiconductor substrate to a material deposition temperature (in step 1630), which decomposes the one or more process gases supplied to the upper process chamber to deposit a material (such as, e.g., a silicon-containing material) on a surface of the semiconductor substrate. In the method 1600 shown in FIG. 16, the semiconductor substrate is heated in step 1630 by: (a) generating heat within a lower heating chamber of the CVD reactor using a heater positioned within the lower heating chamber of the CVD reactor, and (b) conducting the heat generated by the heater to the susceptor positioned within the upper process chamber of the CVD reactor, wherein the heat conducted to the susceptor is distributed uniformly across the susceptor and the semiconductor substrate mounted thereon.

The method 1600 further includes depositing a uniform thickness of the material across the surface of the semiconductor substrate (in step 1640) by: (a) distributing the heat uniformly across the semiconductor substrate, and (b) providing the uniform gas flow of the one or more process gases across the surface of the semiconductor substrate.

The method 1600 may be used to deposit a wide variety of materials on the substrate surface. For example, the method 1600 may be used to deposit a silicon-containing material, a nitrogen-containing material and/or an oxygen-containing material on the substrate surface. In some embodiments of the method 1600, a silicon-containing material may be deposited onto the substrate surface by supplying at least one silicon-containing gas to the upper process chamber in step 1620. Examples of silicon-containing materials that may be deposited on the substrate surface (in step 1640) include, but are not limited to, silicon (Si), poly-silicon (poly-Si), silicon germanium (SiGe), silicon germanium carbide (SiGeC), silicon carbide (SiC), silicon nitride (SiN), silicon carbonitride (SiCN) and silicon carboxide (SiCO). The silicon-containing material deposited in step 1640 may be undoped or doped with boron (B), phosphorus (P), arsenic (As) or indium (In). When depositing silicon germanium (SiGe) on the substrate surface, for example, a combination of silane (SiH₄), germane (GeH₄) and hydrogen (H₂) gases may be supplied to the upper process chamber (in step 1620). When depositing silicon-containing materials, such as SiGe, the semiconductor substrate may be heated (in step 1630) to a relatively high material deposition temperature ranging, for example, between about 500° C. and 900° C. In one embodiment, the material deposition temperature used in step 1130 may be approximately 600° C. In some embodiments, the method 1600 may further include cooling the semiconductor substrate to a lower temperature within a range of about 400° C. to 200° C. before removing the semiconductor substrate from the upper process chamber of the CVD reactor.

In some embodiments, the method 1600 may utilize a gas distribution system as shown in FIGS. 12 and 13B to supply the process gas(es) in step 1620. In such embodiments, step 1620 may include: (a) utilizing a plurality of gas inlets, which are equally spaced around a circular inner sidewall of the upper process chamber, to direct a gas flow of the one or more process gases along a circular inner sidewall of the upper process chamber in a clockwise direction (or a counter-clockwise direction), and (b) exhausting the gas flow of the one or more process gases through the central exhaust port to redirect the gas flow of the one or more process gases radially across the surface of the semiconductor substrate and provide the uniform gas flow of the one or more process gases across the surface of the semiconductor substrate.

In other embodiments, the method 1600 may utilize a gas distribution system as shown in FIGS. 14A-14B and 15B to supply the process gas(es) in step 1620. In such embodiments, step 1620 may include: (a) utilizing a first set of gas inlets positioned along the U-shaped inner sidewall of the upper process chamber to direct a gas flow of the one or more process gases to the angled lower portion of the gas flow plenum; (b) utilizing a second set of gas inlets positioned along the U-shaped inner sidewall of the upper process chamber to direct the gas flow of the one or more process gases around the circular upper portion and through the gas flow slit of the circular upper portion, and (c) exhausting the gas flow directed from the first set of gas inlets and the second set of gas inlets through the central exhaust port to redirect the gas flow radially across the surface of the semiconductor substrate and provide the uniform gas flow of the one or more process gases across the surface of the semiconductor substrate.

Processing systems and methods for depositing materials uniformly across a surface of a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A semiconductor processing system, comprising:
a chemical vapor deposition (CVD) reactor, comprising:
a reactor body having an upper process chamber configured to receive a semiconductor substrate and a lower heating chamber configured to provide heat to the semiconductor substrate during a CVD process performed on a surface of the semiconductor substrate;
a susceptor positioned within the upper process chamber, wherein the semiconductor substrate is mounted on or above the susceptor during the CVD process;
a ceramic resistive heater positioned within the lower heating chamber, wherein the ceramic resistive heater generates the heat provided to the semiconductor substrate during the CVD process; and
a conductive heat spreader coupled between the ceramic resistive heater and the susceptor, wherein the conductive heat spreader conducts the heat generated by the ceramic resistive heater to the susceptor to heat the semiconductor substrate with uniform heat distribution across the semiconductor substrate.

2. The semiconductor processing system of claim 1, wherein the CVD reactor further comprises:
a pedestal configured to: (a) support the semiconductor substrate, (b) transport the semiconductor substrate in and out of the upper process chamber through a loading port coupled to the reactor body, and (c) rest upon an upper surface of the susceptor once transferred into the upper process chamber.

3. The semiconductor processing system of claim 2, wherein the pedestal transfers the heat, which is generated by the ceramic resistive heater and conducted through the conductive heat spreader and the susceptor, to the semiconductor substrate, and wherein the pedestal further improves the uniform heat distribution across the semiconductor substrate.

4. The semiconductor processing system of claim 1, wherein the conductive heat spreader is in direct thermal contact with an upper surface of the ceramic resistive heater and a lower surface of the susceptor.

5. The semiconductor processing system of claim 1, wherein the conductive heat spreader is in: (a) direct thermal contact with an upper surface of the ceramic resistive heater, and (b) indirect thermal contact with a lower surface of the susceptor.

6. The semiconductor processing system of claim 5, further comprising a quartz window coupled between the upper surface the conductive heat spreader and the lower surface of the susceptor, wherein the quartz window conductively and radiatively transfers the heat, which is generated by the ceramic resistive heater and conducted through the conductive heat spreader, to the susceptor.

7. The semiconductor processing system of claim 1, wherein the CVD reactor further comprises:
a water-cooled support plate positioned within the lower heating chamber, wherein the water-cooled support plate provides structural support for the ceramic resistive heater and assists in cooling the ceramic resistive heater.

8. The semiconductor processing system of claim 1, wherein the CVD reactor further comprises:
a water channel within walls of the reactor body, wherein the water channel is configured to cool the upper process chamber and the lower heating chamber.

9. The semiconductor processing system of claim 1, wherein the ceramic resistive heater comprises a plurality of pyrolytic graphite (PG) resistive heating elements, a plurality of power connectors electrically connected to the plurality of PG resistive heating elements, and a pyrolytic boron nitride (PBN) upper layer formed above a PBN backplate.

10. The semiconductor processing system of claim 9, wherein the plurality of power connectors are arranged peripherally around a circumference of the ceramic resistive heater and coupled to the plurality of PG resistive heating elements through PG interconnects.

11. The semiconductor processing system of claim 9, wherein the plurality of power connectors are positioned below a lower surface of the ceramic resistive heater to avoid interfering with an upper surface of the ceramic resistive heater.

12. The semiconductor processing system of claim 9, wherein the CVD reactor further comprises:
a water-cooled support plate positioned within the lower heating chamber, wherein the water-cooled support plate provides structural support for the ceramic resistive heater and assists in cooling the ceramic resistive heater; and
wherein the plurality of power connectors are positioned below the water-cooled support plate to avoid interfering with an upper surface of the ceramic resistive heater.

13. The semiconductor processing system of claim 1, wherein the CVD reactor further comprises:
a central exhaust port coupled to the upper process chamber; and
a plurality of gas inlets distributed around a periphery of the upper process chamber, wherein the plurality of gas inlets supply one or more process gases to the upper process chamber to pressurize the upper process chamber and provide uniform gas flow of the one or more process gases across the surface of the semiconductor substrate to the central exhaust port.

14. The semiconductor processing system of claim 13, wherein the CVD reactor further comprises:
a lower gas inlet coupled to the lower heating chamber, wherein the lower gas inlet supplies an inert gas to the lower heating chamber to pressurize the lower heating chamber; and
a lower exhaust port coupled to the lower heating chamber to remove the inert gas supplied to the lower heating chamber.

15. The semiconductor processing system of claim 14, wherein the upper process chamber and the lower heating chamber are independently pressurized to equalize pressure in the upper process chamber and the lower heating chamber during the CVD process.

16. A method for depositing material on a semiconductor substrate, the method comprising:
mounting the semiconductor substrate on or above a susceptor positioned within an upper process chamber of a chemical vapor deposition (CVD) reactor;
supplying one or more process gases to the upper process chamber of the CVD reactor;
heating the semiconductor substrate to a material deposition temperature, wherein the material deposition temperature decomposes the one or more process gases supplied to the upper process chamber to deposit a material on a surface of the semiconductor substrate, wherein said heating the semiconductor substrate to the material deposition temperature comprises:
generating heat within a lower heating chamber of the CVD reactor using a ceramic resistive heater positioned within the lower heating chamber of the CVD reactor; and
conducting the heat generated by the ceramic resistive heater through a conductive heat spreader to the susceptor, wherein the conductive heat spreader distributes the heat uniformly across the susceptor and the semiconductor substrate; and
depositing a uniform thickness of the material across the surface of the semiconductor substrate by distributing the heat uniformly across the semiconductor substrate.

17. The method of claim 16, wherein said supplying the one or more process gases to the upper process chamber of the CVD reactor comprises:
supplying the one or more process gases via a plurality of gas inlets, which are distributed around a periphery of the upper process chamber to provide uniform gas flow of the one or more process gases across the surface of the semiconductor substrate to a central exhaust port coupled to the upper process chamber; and
wherein said depositing the uniform thickness of the material across the surface of the semiconductor substrate is achieved by: (a) distributing the heat uniformly across the semiconductor substrate, and (b) providing the uniform gas flow of the one or more process gases across the surface of the semiconductor substrate.

18. The method of claim 16, wherein said supplying the one or more process gases to the upper process chamber of the CVD reactor comprises supplying a silicon-containing gas to the upper process chamber of the CVD reactor, and wherein the material deposited across the surface of the semiconductor substrate comprises silicon (Si), poly-silicon (poly-Si), silicon germanium (SiGe), silicon germanium carbide (SiGeC), silicon carbide (SiC), silicon nitride (SiN), silicon carbonitride (SiCN) or silicon carboxide (SiCO), each of which is undoped or doped with boron (B), phosphorus (P), arsenic (As) or indium (In).

19. The method of claim 18, wherein said heating the semiconductor substrate to the material deposition temperature comprises heating the semiconductor substrate to a temperature within a range of 500°C to 900°C.

20. The method of claim 16, wherein before said supplying the one or more process gases to the upper process chamber of the CVD reactor, the method further comprises precleaning the surface of the semiconductor substrate by:
supplying one or more precleaning gases to the upper process chamber of the CVD reactor; and
heating the semiconductor substrate to a precleaning temperature, wherein the precleaning temperature causes the one or more precleaning gases to react with and remove contaminants from the surface of the semiconductor substrate, and wherein said heating the semiconductor substrate to the precleaning temperature comprises:
generating heat within the lower heating chamber of the CVD reactor using the ceramic resistive heater positioned within the lower heating chamber of the CVD reactor; and
conducting the heat generated by the ceramic resistive heater through the conductive heat spreader to the susceptor, wherein the conductive heat spreader distributes the heat uniformly across the susceptor and the semiconductor substrate.

21. The method of claim 20, wherein said supplying the one or more precleaning gases to the upper process chamber of the CVD reactor comprises supplying hydrogen (H₂) gas to the upper process chamber of the CVD reactor.

22. The method of claim 21, wherein said heating the semiconductor substrate to the precleaning temperature comprises heating the semiconductor substrate to a temperature within a range of 700°C to 1100°C.
